(19) United States
(12) Patent Application Publication
(10) Pub. No.: US 2012/0292607 A1
(43) Pub. Date: Nov. 22, 2012

(54) ORGANIC ELECTROLUMINESCENCE DEVICE

(75) Inventors: Toru Watanabe, Kanagawa (JP); Tetsu Kitamura, Kanagawa (JP); Toshihiro Ise, Kanagawa (JP)

(73) Assignee: FUJIFILM CORPORATION, Tokyo (JP)

(21) Appl. No.: 13/521,973

(22) PCT Filed: Dec. 28, 2010
(86) PCT No.: PCT/JP2010/073817

§ 371 Date: Jul. 12, 2012

(30) Foreign Application Priority Data
Jan. 15, 2010 (JP) 2010-007536
May 20, 2010 (JP) 2010-116665
Nov. 25, 2010 (JP) 2010-263017

(51) Int. Cl. H01L 51/54; C09K 11/06

(52) U.S. Cl. 257/40; 252/301.16; 257/E51.026

(57) ABSTRACT

As an organic electroluminescence device that exhibits superior external quantum efficiency and durability during driving at high temperature, and small variation in chromaticity and small increase in voltage after high-temperature driving, it is provided that the organic electroluminescence device including on a substrate a pair of electrodes and at least one layer of an organic layer including a light emitting layer disposed between the electrodes, wherein the light emitting layer contains at least one specific blue phosphorescent iridium complex and any layer of the at least one layer of an organic layer contains at least one compound represented by Formula (1):

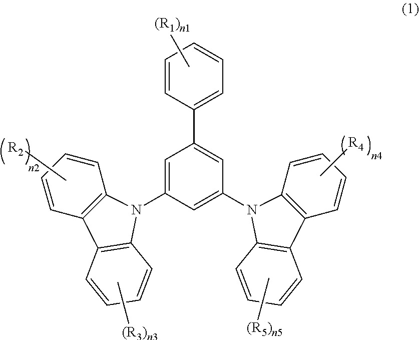

wherein in Formula (1), each of R₁ to R₅ independently represents a specific group or atom, n1 represents an integer of 0 to 5, and each of n2 to n5 independently represents an integer of 0 to 4.

### TECHNICAL FIELD

The present invention relates to an organic electroluminescence device (hereinafter, also referred to as a “device” or an “organic EL device”). More specifically, the present invention relates to an organic electroluminescence device that exhibits superior properties of devices required for driving at high temperatures (specifically, external quantum efficiency, durability, variation in chromaticity and variation in voltage).

### BACKGROUND ART

An organic electroluminescence device is being actively researched and developed, since it can emit light with high luminance intensity through driving at a low voltage. Generally, the organic electroluminescence device includes an organic layer including a light emitting layer and a pair of electrodes disposed via the layer and emits light using energy of excitons produced by recombination of electrons injected from a cathode with holes injected from an anode in the light emitting layer.

Recently, efficiency of device is increased using a phosphorescent light emitting material. For example, organic electroluminescence devices that exhibit improved light emitting efficiency and heat resistance through use of an iridium or platinum complex as the phosphorescent light emitting material is researched.

In addition, a dope-type device using a light emitting layer in which a light emitting material is doped into a host material is widely used.

Recently, host materials are actively developed and, for example, Patent Documents 1 and 2 discloses a device using a carbazole compound in which a plurality of aryl groups are combined to one another, as a host material, for the purpose of manufacturing devices that have superior light emitting efficiency, decreased pixel defects and excellent heat resistance.

In addition, regarding the light emitting material, Patent Document 3 discloses an invention using a condensed ring-type phosphorescent light emitting material to obtain a device that can emit blue light, exhibits superior durability, and has a sharp luminescent spectrum and low consumption. Also, Patent Document 4 discloses a condensed ring type phosphorescent light emitting material having a specific structure.

However, conventional devices have disadvantages of low durability during high-temperature driving and great variation in chromaticity and great increase in voltage after driving at high temperatures. For this reason, there is a need for solutions to these problems.

### RELATED ART

### Patent Document

Patent Document 1: WO 04/074399
Patent Document 2: WO 08/072,538
Patent Document 3: US Patent Application Publication No. 2008/297033
Patent Document 4: WO 07/095,118

### DISCLOSURE OF INVENTION

### Problems to be Solved by the Invention

However, conventional devices have disadvantages of low durability during high-temperature driving and great variation in chromaticity and great increase in voltage after driving at high temperatures. For this reason, there is a need for solutions to these problems.

The inventors of the present invention discovered that devices which exhibit superior properties such as external quantum efficiency and durability during high-temperature driving, small variation in chromaticity and small increase in voltage after driving at high temperatures are unexpectedly obtained, as compared to commonly used mCBP when a host material of the present invention is used in combination with a specific blue phosphorescent material.

That is, it is one object of the present invention to provide an organic electroluminescence device that exhibits superior external quantum efficiency and durability during driving at high temperature, and small variation in chromaticity and small increase in voltage after high-temperature driving.

In addition, it is another object of the present invention to provide a light emitting layer and a composition useful for the organic electroluminescence device. Furthermore, it is another object of the present invention to provide a light emission apparatus, display apparatus and an illumination apparatus including the organic electroluminescence device.

### Means for Solving the Problems

That is, the present invention is accomplished by the following means.

[1] An organic electroluminescence device, comprising on a substrate:

a pair of electrodes; and

at least one layer of an organic layer including a light emitting layer disposed between the electrodes,

wherein the light emitting layer contains at least one compound represented by Formula (PI-1), and

any layer of the at least one layer of an organic layer contains at least one compound represented by Formula (1):

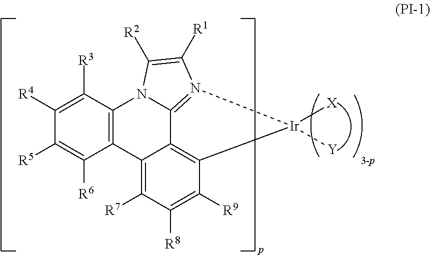

wherein in Formula (PI-1), each of R¹ to R⁹ independently represents a hydrogen atom or a substitutent, and the substituents represented by R¹ to R⁹ may be combined together to form a ring;

(X-Y) represents a monoanionic bidentate ligand; and

p represents an integer of 1 to 3:

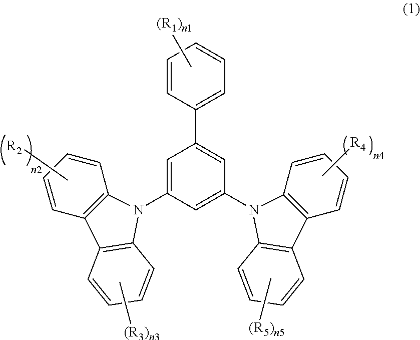

wherein in Formula (1), R₁ represents an alkyl group, an aryl group or a silyl group and may further have a substituent Z, provided that R₁ does not represent a carbazolyl group or a perfluoroalkyl alkyl group, and when R₁ is present in plural, each of a plurality of R₁'s may be the same as or different from every other R₁, and a plurality of R₁'s may be combined together to form an aryl ring which may have a substituent Z;

each of R₂ to R₅ independently represents an alkyl group, an aryl group, a silyl group, a cyano group or a fluorine atom and may further have a substituent Z, and when each of R₂ to R₅ is present in plural, each of a plurality of R₂'s to a plurality of R₅'s may be the same as or different from every other R₂ to R₅, respectively;

the substituent Z represents an alkyl group, an alkenyl group, an aryl group, an aromatic heterocyclic group, an alkoxy group, a phenoxy group, a fluorine atom, a silyl group, an amino group, a cyano group or a group formed by a combination thereof, and a plurality of the substituent Z's may be combined together to form an aryl group;

n1 represents an integer of 0 to 5; and

each of n2 to n5 independently represents an integer of 0 to 4.

[2] The organic electroluminescence device as described in [1] above,

wherein in Formula (PI-1), p is 3.

[3] The organic electroluminescence device as described in [1] or [2] above,

wherein the compound represented by Formula (1) is used in the light emitting layer.

[4] The organic electroluminescence device as described in any one of [1] to [3] above,

wherein the compound represented by Formula (1) is used in a layer disposed between the light emitting layer and a cathode.

[5] The organic electroluminescence device as described in any one of [1] to [3] above,

wherein the compound represented by Formula (1) is used in a layer disposed between the light emitting layer and an anode.

[6] The organic electroluminescence device as described in any one of [1] to [5] above,

wherein the compound represented by Formula (1) above is represented by the following Formula (2):

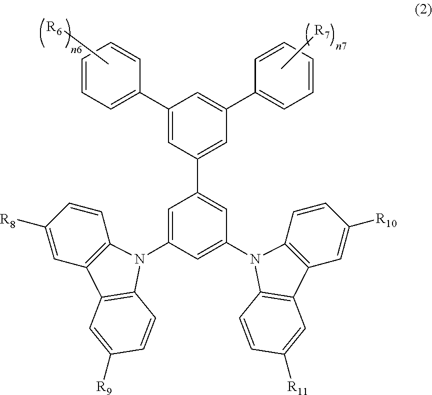

wherein in Formula (2), each of R₆ and R₇ independently represents an alkyl group which may have a substituent Z, an aryl group which may have an alkyl group, a cyano group or a fluorine atom, and when each of R₆ and R₇ is present in plural, each of a plurality of R₆'s and a plurality of R₇'s may be the same as or different from every other R₆ and R₇, respectively, and each of the plurality of R₆'s and the plurality of R₇'s may be combined together to form an aryl ring that may have a substituent Z;

each of n6 and n7 independently represents an integer of 0 to 5;

each of R₈ to R₁₁ independently represents a hydrogen atom, an alkyl group which may have a substituent Z, an aryl group which may have an alkyl group, a silyl group which may have a substituent Z, a cyano group or a fluorine atom; and

the substituent Z represents an alkyl group, an alkenyl group, an aryl group, an aromatic heterocyclic group, an alkoxy group, a phenoxy group, a fluorine atom, a silyl group, an amino group, a cyano group or a group formed by a combination thereof, and a plurality of substituent Z's may be combined together to form an aryl group.

[7] The organic electroluminescence device as described in [6] above,

wherein in Formula (PI-1), each of R¹ to R⁹ independently represents a hydrogen atom, an alkyl group, an aryl group, a cyano group or a fluorine atom, R¹ to R⁹ may be combined together to form an aryl group, and p is 3, in Formula (2), each of R₆ and R₇ independently represents an alkyl group or an aryl group which may have an alkyl group, each of n₆ and n₇ independently represents an integer of 0 to 2, each of R₈ to R₁₁ independently represents a hydrogen atom, an alkyl group, an aryl group which may have an alkyl group, a silyl group substituted by an alkyl group or a phenyl group, a cyano group or a fluorine atom.

[8] The organic electroluminescence device as described in any one of [1] to [7] above,

wherein in Formula (PI-1), R⁸ is a hydrogen atom or a fluorine atom.

[9] The organic electroluminescence device as described in any one of [1] to [8] above, further comprising:

an electron injection layer disposed between the electrodes,

wherein the electron injection layer contains an electron donating dopant.

[10] The organic electroluminescence device as described in any one of [1] to [9] above, further comprising:

a hole injection layer disposed between the electrodes,

wherein the hole injection layer contains a hole accepting dopant.

[11] The organic electroluminescence device as described in any one of [1] to [10] above,

wherein at least one layer of the organic layer disposed between the pair of electrodes is formed by a solution coating process.

[12] A light emitting layer, comprising:

the compound represented by Formula (PI-1) and the compound represented by Formula (1) as described in any one of [1] to [3] above.

[13] A composition, comprising:

the compound represented by Formula (PI-1) and the compound represented by Formula (1) as described in any one of [1] to [3] above.

[14] A light emission apparatus using the organic electroluminescence device as described in any one of [1] to [11] above.

[15] A display apparatus using the organic electroluminescence device as described in any one of [1] to [11] above.

[16] An illumination apparatus using the organic electroluminescence device as described in any one of [1] to [11] above.

### Effects of the Invention

The organic electroluminescence device of the present invention exhibits superior device properties during driving at high temperatures. Specifically, the organic electroluminescence device of the present invention exhibits superior external quantum efficiency and high durability during driving at high temperatures, and small variation in chromaticity and small increase in voltage after high-temperature driving.

### BRIEF DESCRIPTION OF DRAWINGS

FIG. 1 is a schematic view illustrating one example of a layer structure of an organic EL device according to the present invention (a first embodiment);

FIG. 2 is a schematic view illustrating one example of a light emission apparatus according to the present invention (a second embodiment); and

FIG. 3 is a schematic view illustrating one example of an illumination apparatus according to the present invention (a third embodiment).

### EMBODIMENTS FOR CARRYING OUT THE INVENTION

Hereinafter, in the description of Formula (PI-1), Formula (PIL-1), Formula (1) and Formula (2), a hydrogen atom includes an isotope (such as heavy hydrogen atom) and, furthermore, an atom constituting a substituent also includes an isotope thereof In the present invention, a substituent group A and a substituent Z are defined as follows.

(Substituent Group A)

An alkyl group (preferably 1 to 30 carbon atoms, more preferably 1 to 20 carbon atoms, particularly preferably 1 to 10 carbon atoms and examples thereof include methyl, ethyl, isopropyl, t-butyl, n-octyl, n-decyl, n-hexadecyl, cyclopropyl, cyclopentyl, cyclohexyl, neopentyl and the like), an alkenyl group (preferably 2 to 30 carbon atoms, more preferably 2 to 20 carbon atoms, particularly preferably 2 to 10 carbon atoms, and examples thereof include vinyl, allyl, 2-butenyl, 3-pentenyl and the like), an alkynyl group (preferably 2 to 30 carbon atoms, more preferably 2 to 20 carbon atoms, particularly preferably 2 to 10 carbon atoms, and examples thereof include propargyl, 3-pentynyl and the like), an aryl group (preferably 6 to 30 carbon atoms, more preferably 6 to 20 carbon atoms, particularly preferably 6 to 12 carbon atoms, examples thereof include phenyl, 4-methylphenyl, 2,6-dimethylphenyl and the like), an amino group (preferably 0 to 30 carbon atoms, more preferably 0 to 20 carbon atoms, particularly preferably 0 to 10 carbon atoms, examples thereof include amino, methylamino, dimethylamino, diethylamino, dibenzylamino, diphenylamino, ditolylamino and the like), an alkoxy group (preferably 1 to 30 carbon atoms, more preferably 1 to 20 carbon atoms, particularly preferably 1 to 10 carbon atoms, and examples thereof include methoxy, ethoxy, butoxy, 2-ethylhexyloxy and the like), an aryloxy group (preferably 6 to 30 carbon atoms, more preferably 6 to 20 carbon atoms, particularly preferably 6 to 12 carbon atoms, and examples thereof include phenyloxy, 1-naphthyloxy, 2-naphthyloxy and the like), a heterocyclic oxy group (preferably 1 to 30 carbon atoms, more preferably 1 to 20 carbon atoms, particularly preferably 1 to 12 carbon atoms, and examples thereof include pyridyloxy, pyrazyloxy, pyrimidyloxy, quinolyloxy and the like), an acyl group (preferably 2 to 30 carbon atoms, more preferably 2 to 20 carbon atoms, particularly preferably 2 to 12 carbon atoms, and examples thereof include acetyl, benzoyl, formyl, pivaloyl and the like), an alkoxycarbonyl group (preferably 2 to 30 carbon atoms, more preferably 2 to 20 carbon atoms, particularly preferably 2 to 12 carbon atoms, and examples thereof include methoxycarbonyl, ethoxycarbonyl and the like), an aryloxycarbonyl group (preferably 7 to 30 carbon atoms, more preferably 7 to 20 carbon atoms, particularly preferably 7 to 12 carbon atoms, and examples thereof include phenyloxycarbonyl), an acyloxy group (preferably 2 to 30 carbon atoms, more preferably 2 to 20 carbon atoms, particularly preferably 2 to 10 carbon atoms, and examples thereof include acetoxy, benzoyloxy and the like, an acylamino group (preferably 2 to 30 carbon atoms, more preferably 2 to 20 carbon atoms, particularly preferably 2 to 10 carbon atoms, and examples thereof include acetylamino, benzoylamino and the like), an alkoxycarbonylamino group (preferably 2 to 30 carbon atoms, more preferably 2 to 20 carbon atoms, particularly preferably 2 to 12 carbon atoms, and examples thereof include methoxycarbonylamino and the like), an aryloxycarbonylamino group (preferably 7 to 30 carbon atoms, more preferably 7 to 20 carbon atoms, particularly preferably 7 to 12 carbon atoms, and examples thereof include phenyloxycarbonylamino), a sulfonylamino group (preferably 1 to 30 carbon atoms, more preferably 1 to 20 carbon atoms, particularly preferably 1 to 12 carbon atoms, and examples thereof include methanesulfonylamino, benzenesulfonylamino and the like), a sulfamoyl group (preferably 0 to 30 carbon atoms, more preferably 0 to 20 carbon atoms, particularly preferably 0 to 12 carbon atoms, and examples thereof include sulfamoyl, methylsulfamoyl, dimethylsulfamoyl, phenylsulfamoyl and the like), a carbamoyl group (preferably 1 to 30 carbon atoms, more preferably 1 to 20 carbon atoms, particularly preferably 1 to 12 carbon atoms, and examples thereof include carbamoyl, methylcarbamoyl, diethylcarbamoyl, phenylcarbamoyl and the like), an alkylthio group (preferably 1 to 30 carbon atoms, more preferably 1 to 20 carbon atoms, particularly preferably 1 to 12 carbon atoms, and examples thereof include methylthio, ethylthio and the like), an arylthio group (preferably 6 to 30 carbon atoms, more preferably 6 to 20 carbon atoms, particularly preferably 6 to 12 carbon atoms, and examples thereof include phenylthio and the like), a heterocyclic thio group (preferably 1 to 30 carbon atoms, more preferably 1 to 20 carbon atoms, particularly preferably 1 to 12 carbon atoms, and examples thereof include pyridylthio, 2-benzimizolylthio, 2-benzoxazolylthio, 2-benzthiazolylthio and the like), a sulfonyl group (preferably 1 to 30 carbon atoms, more preferably 1 to 20 carbon atoms, particularly preferably 1 to 12 carbon atoms, and examples thereof include mesyl, tosyl and the like), a sulfinyl group (preferably 1 to 30 carbon atoms, more preferably 1 to 20 carbon atoms, particularly preferably 1 to 12 carbon atoms, and examples thereof include methanesulfinyl, benzenesulfinyl and the like), a ureido group (preferably 1 to 30 carbon atoms, more preferably 1 to 20 carbon atoms, particularly preferably 1 to 12 carbon atoms, and examples thereof include ureido, methylureido, phenylureido and the like), a phosphoric acid amide group (preferably 1 to 30 carbon atoms, more preferably 1 to 20 carbon atoms, particularly preferably 1 to 12 carbon atoms and examples thereof include diethylphosphoric amide, phenylphosphoric amide and the like), a hydroxyl group, a mercapto group, a halogen atom (for example, a fluorine atom, chlorine atom, a bromine atom, an iodine atom), a cyano group, a sulfo group, a carboxyl group, a nitro group, a hydroxamic acid group, a sulfino group, a hydrazine group, an imino group, a heterocyclic group (including an aromatic heterocyclic group, preferably 1 to 30 carbon atoms, more preferably 1 to 12 carbon atoms, and examples thereof include hetero atoms such as nitrogen atom, oxygen atom, sulfur atom, phosphrous atom, silicon atom, selenium atom, and terillium atom, specific examples thereof include pyridyl, pyrazinyl, pyrimidyl, pyridazinyl, pyrrolyl, pyrazolyl, triazolyl, imidazolyl, oxazolyl, thiazolyl, isoxazolyl, isothiazolyl, quinolyl, furyl, thienyl, selenophenyl, tellurophenyl, piperidyl, piperidino, morpholino, pyrrolidyl, pyrrolizino, benzoxazolyl, benzimidazolyl, benzothiazolyl, carbazolyl, azepinyl and silolyl groups and the like), a silyl group (preferably 3 to 40 carbon atoms, more preferably 3 to 30 carbon atoms, particularly preferably 3 to 24 carbon atoms, and examples thereof include trimethylsilyl, triphenylsilyl and the like), a silyloxy group (preferably 3 to 40 carbon atoms, more preferably 3 to 30 carbon atoms, particularly preferably 3 to 24 carbon atoms, and examples thereof include trimethylsilyl(silyl)oxy, triphenylsilyloxy and the like), a phosphoryl group (examples thereof include a diphenylphosphoryl group, a dimethylphosphoryl group and the like). These substituents may be further substituted and examples of the further substituent include groups selected from the aforementioned substituent group A.

### (Substituent Z)

The substituent Z represents an alkyl group, an alkenyl group, an aryl group, aromatic heterocyclic group, an alkoxy group, a phenoxy group, a fluorine atom, a silyl group, an amino group, a cyano group or a group formed by combination thereof. A plurality of substituents Z may be combined together to form an aryl group.

The alkyl group represented by the substituent Z preferably is an alkyl group having 1 to 8 carbon atoms, more preferably, an alkyl group having 1 to 6 carbon atoms. Examples of the alkyl group include a methyl group, an ethyl group, an n-propyl group, an isopropyl group, an isobutyl group, a t-butyl group, an n-butyl group, a cyclopropyl group and the like. A methyl group, an ethyl group, isobutyl group or t-butyl group is preferred and a methyl group is more preferred.

The alkenyl group represented by the substituent Z preferably is an alkenyl group having 2 to 8 carbon atoms, more preferably an alkenyl group having 2 to 6 carbon atoms. Examples of the alkenyl group include a vinyl group, an n-propenyl group, an isopropenyl group, an isobutenyl group, an n-butenyl group and the like. A vinyl group, n-propenyl group, isobutenyl group or n-butenyl group is preferred and a vinyl group is more preferred.

The aryl group represented by the substituent Z is preferably an aryl group having 6 to 18 carbon atoms, more preferably an aryl group having 6 to 12 carbon atoms. Examples thereof include a phenyl group, a biphenyl group, a naphthyl group, a tollyl group, a xylyl and the like. Among them, a phenyl group and a biphenyl group are preferred and a phenyl group is more preferred.

The aromatic heterocyclic group represented by the substituent Z is preferably an aromatic heterocyclic group having 4 to 12 carbon atoms, and examples of the aromatic heterocyclic group include a pyridyl group, a furyl group, a thienyl group and the like. A pyridyl group or a furyl group is preferred, and a pyridyl group is more preferred.

The alkoxy group represented by the substituent Z is preferably an alkoxy group having 1 to 8 carbon atoms, more preferably an alkoxy group having 1 to 4 carbon atoms. Examples of the alkoxy group include a methoxy group, an ethoxy group, an n-propoxy group, an isopropoxy group, an isobutoxy group, a t-butoxy group, an n-butoxy group, a cyclopropyloxy group and the like. A methoxy group, an ethoxy group, an isobutoxy group, or a t-butoxy group is preferred and a methoxy group is more preferred.

The silyl and amino groups represented by the substituent Z are the same as the silyl and amino groups of the aforementioned substituent group A.

Examples of the aryl ring formed by combining a plurality of substituents Z together include a benzene ring, a naphthalene ring and the like. A benzene ring is preferred.

The organic electroluminescence device of the present invention is an organic electroluminescence device that includes on a substrate a pair of electrodes; and at least one organic layer including a light emitting layer disposed between the electrodes, wherein the light emitting layer contains at least one compound represented by Formula (PI-1) and one of the at least one organic layer contains at least one compound represented by Formula (1).

[Compound Represented by Formula (PI-1)]

Hereinafter, the compound represented by Formula (PI-1) will be described.

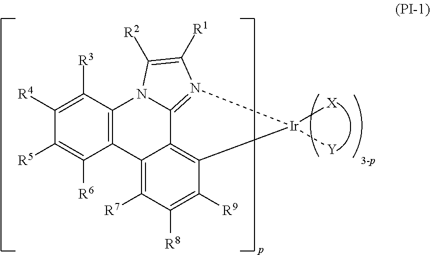

In Formula (PI-1), each of R¹ to R⁹ independently represents a hydrogen atom or a substituent. The substituents represented by R¹ to R⁹ may be combined together to form a ring.

(X-Y) represents a monoanionic bidentate ligand.

p represents an integer of 1 to 3.

The substituents represented by R¹ to R⁹ independently include a substituent selected from the group consisting of the above-mentioned substituent group A. The substituents represented by R¹ to R⁹ may be combined together to form a ring.

R¹ to R⁹ preferably independently represents a hydrogen atom, an alkyl group, a cycloalkyl group, an alkylthio group, an aryl group, a heteroaryl group, a cyano group, a fluorine atom, an alkoxy group, an aryloxy group, a dialkylamino group or a diarylamino group, more preferably a hydrogen atom, an alkyl group, an aryl group, a cyano group or a fluorine atom, more preferably a hydrogen atom, an alkyl group, an aryl group or a fluorine atom.

The alkyl group represented by R¹ to R⁹ may have a substituent and may be saturated or unsaturated. The substituent of the alkyl group having a substituent may be the aforementioned substituent Z and the substituent Z is preferably a fluorine atom. The alkyl group represented by R¹ to R⁹ is preferably an alkyl group having 1 to 8 carbon atoms, more preferably an alkyl group having 1 to 6 carbon atoms, and examples thereof include a methyl group, a trifluoromethyl group, an ethyl group, a vinyl group, an n-propyl group, an isopropyl group, an isobutyl group, a t-butyl group, an n-butyl group, a neopentyl group, an n-hexyl group and the like. A methyl group, an ethyl group, an isopropyl group, a t-butyl group, a neopentyl group, or an n-hexyl group is preferred, a methyl group, an isopropyl group, a t-butyl group, a neopentyl group, or an n-hexyl group is more preferred.

Each of the cycloalkyl group represented by R¹ to R⁹ may independently have a substituent, and may be saturated or unsaturated. The substituent of the cycloalkyl group having a substituent may be the aforementioned substituent Z and the substituent Z is preferably an alkyl group. The cycloalkyl group represented by R¹ to R⁹ is preferably a cycloalkyl group having 3 to 20 carbon atoms, more preferably a cycloalkyl group having 3 to 10 carbon atoms, even more preferably a cycloalkyl group having 5 to 10 carbon atoms. Examples of the cycloalkyl group include a cyclopentyl group, a cyclohexyl group, a cycloheptyl group, a cyclooctyl group, a cyclohexenyl group and the like. A cyclopentyl group, a cyclohexyl group or cycloheptyl group is preferred.

Each of the alkylthio groups represented by R¹ to R⁹ may independently have a substituent, and may be saturated or unsaturated. The substituent of the cycloalkyl group having a substituent may be the aforementioned substituent Z and the substituent Z is preferably a fluorine atom. The alkylthio group represented by R¹ to R⁹ has preferably 1 to 30 carbon atoms, more preferably 1 to 20 carbon atoms, more preferably 1 to 12 carbon atoms, even more preferably 1 to 6 carbon atoms, and examples thereof include a methylthio group, an ethylthio group, an n-propylthio group, an isopropylthio group, an isobutylthio group, a t-butylthio group, an n-butylthio group, a neopentylthio group, an n-hexylthio group and the like. A methylthio group and an ethylthio group are preferred and a methylthio group is more preferred.

Each of the aryl groups represented by R¹ to R⁹ may be independently condensed and may have a substituent. The substituent of the aryl group having a substituent may be the aforementioned substituent Z, and the substituent Z is preferably an alkyl group or an aryl group, more preferably an alkyl group. The aryl group represented by R¹ to R⁹ is preferably an aryl group having 6 to 18 carbon atoms which may have an alkyl group having 1 to 6 carbon atoms or a phenyl group, more preferably an aryl group having 6 to 12 carbon atoms which may have an alkyl group having 1 to 4 carbon atoms. Examples thereof include a phenyl group, a methylphenyl group, a dimethylphenyl group, a trimethylphenyl group, an isopropylphenyl group, a diphenylphenyl group and the like. A phenyl group, a 2-methylphenyl group, a 2,6-dimethylphenyl group, a 2,4,6-trimethylphenyl group, a 4-isopropylphenyl group, or a 2,6-diphenylphenyl group is preferred and a 2,6-dimethylphenyl group is more preferred.

Each of the heteroaryl group represented by R¹ to R⁹ may be independently condensed and may have a substituent. The substituent of the aryl group having a substituent may be the aforementioned substituent Z, and the substituent Z is preferably an alkyl group or an aryl group, more preferably an alkyl group. The heteroaryl group represented by R¹ to R⁹ is preferably a heteroaryl group having 4 to 12 carbon atoms and more preferably a heteroaryl group having 4 to 10 carbon atoms. Examples thereof include a pyridyl group, a furyl group and the like and a pyridyl group is preferred.

The alkoxy group represented by R¹ to R⁹ is preferably an alkoxy group having 1 to 8 carbon atoms, more preferably an alkoxy group having 1 to 4 carbon atoms, examples thereof include a methoxy group, an ethoxy group, an n-propyloxy group, an isopropoxy group, an isobutoxy group, a t-butoxy group, an n-butoxy group, a cyclopropoxy and the like. A methoxy group, an ethoxy group, an isobutoxy group or a t-butoxy group is preferred and a methoxy group is more preferred.

The aryloxy group represented by R¹ to R⁹ is preferably an aryloxy group having 6 to 12 carbon atoms, more preferably an aryloxy group having 6 to 10 carbon atoms, and examples thereof include a phenoxy group, a biphenyloxy group and the like, and a phenoxy group is preferred.

The dialkylamino group represented by R¹ to R⁹ is preferably a dialkylamino group having 2 to 16 carbon atoms, more preferably a dialkylamino group having 2 to 12 carbon atoms, and examples thereof include a dimethylamino group, a diethylamino group and the like. A dimethylamino group is preferred.

The diarylamino group represented by R¹ to R⁹ is preferably a diarylamino group having 12 to 24 carbon atoms, more preferably a diarylamino group having 12 to 20 carbon atoms, and examples thereof include a diphenylamino group, a dinaphthylamino and the like. A diphenylamino group is preferred.

The substituents represented by R¹ to R⁹ may be combined together to form a ring. When the ring is formed, the formation is preferably carried out by combining adjacent two groups of R¹ to R⁹ together, and is more preferably by combining R¹ with R² together. The formed ring is a cycloalkyl ring, an aryl ring, a heteroaryl group and the like, an aryl ring or a heteroaryl ring is preferred, and an aryl ring is more preferred. The formed ring may have the aforementioned substituent Z, and the substituent Z is preferably an alkyl group, an alkenyl group or an aryl group, more preferably an alkyl group. In addition, a plurality of substituents Z are preferably combined together to form an aryl ring.

The formed cycloalkyl ring is preferably a cycloalkyl ring having 5 to 30 carbon atoms, more preferably a cycloalkyl ring having 5 to 14 carbon atoms, including carbon atoms associated with the formation of ring other than R¹ to R⁹. Examples of the formed cycloalkyl ring include a cyclopentyl ring, a cyclohexyl ring and an indane ring. A cyclohexyl ring or indane ring is preferred and an indane ring is more preferred.

The formed aryl ring is preferably an aryl ring having 6 to 30 carbon atoms, more preferably an aryl ring having 6 to 14 carbon atoms, including carbon atoms associated with the formation of ring other than R¹ to R⁹. Examples of the formed aryl ring include a benzene ring, a naphthalene ring, a phenanthrene ring and the like, which may have an alkyl group. A benzene ring which may have an alkyl group is preferred and a benzene ring is more preferred.

The formed heteroaryl ring is preferably an heteroaryl ring having 4 to 12 carbon atoms, more preferably a heteroaryl ring having 4 to 10 carbon atoms, including carbon atoms associated with the formation of ring other than R¹ to R⁹. Examples of the formed heteroaryl ring include an indole ring, a pyridine ring, a pyrazine ring, a furan ring, a thiophene ring and the like. A pyrazine ring is preferred.

R¹ and R² are preferably a hydrogen atom, an alkyl group, an aryl group (preferably a phenyl group which may have a substituent Z and the substituent Z is preferably an alkyl group or an aryl group, more preferably a methyl group, a phenyl group), a heteroaryl group, an alkoxy group, an alkylthio group, a dialkylamino group, or a group in which R¹ and R² are combined together to form a benzene ring which may have a substituent Z (substituent Z is preferably an alkyl group), or a group in which R¹ and R² are combined together to form a pyrazine ring which may have a substituent Z (pyrazine ring is preferably a unsaturated pyrazine ring), more preferably, a hydrogen atom, an alkyl group, an aryl group, a group in which R¹ and R² are combined together to form a benzene ring which may have a substituent Z (substituent Z is preferably an alkyl group), more preferably a hydrogen atom, a methyl group, an ethyl group, an isopropyl group, a t-butyl group, a neopentyl group, a phenyl group which may have a substituent Z (substituent Z is preferably an alkyl group, more preferably a methyl group).

R³, R⁴, R⁵ and R⁶ are preferably a hydrogen atom, an alkyl group, an aryl group, a cycloalkyl group, more preferably a hydrogen atom, an alkyl group, an aryl group (aryl group is preferably a phenyl group which may have a substituent Z, the substituent Z is preferably an alkyl group, more preferably a methyl group, an isopropyl group), more preferably a hydrogen atom and an alkyl group, particularly preferably a hydrogen atom, a methyl group, an ethyl group, an isopropyl group, a t-butyl group, a neopentyl group, and an n-hexyl group.

R⁷ is preferably a hydrogen atom, an alkyl group, an aryl group (aryl group is preferably a phenyl group which may have a substituent Z, and the substituent Z is preferably an alkyl group, more preferably a methyl group), more preferably a hydrogen atom and an alkyl group, even more preferably a hydrogen atom, a methyl group, an ethyl group, an isopropyl group, a t-butyl group, and a neopentyl group.

R⁸ is preferably a hydrogen atom, an alkyl group, a fluorine atom, and an aryl group, more preferably a hydrogen atom, an alkyl group, a fluorine atom, even more preferably a hydrogen atom and a fluorine atom. When R⁸ is a hydrogen atom or a fluorine atom, a device which exhibits superior external quantum efficiency and durability during driving at high temperatures, and small variation in voltage after driving at a high temperature is obtained, although the reason is not clear.

R⁹ is preferably a hydrogen atom, an alkyl group and an aryl group, more preferably a hydrogen atom and alkyl group, even more preferably a hydrogen atom.

p is preferably 2 or 3, more preferably 3.

(X-Y) represents a monoanionic bidentate ligand. It is thought that these ligands do not directly contribute to photoactivity and can change photoactivity of molecules. The monoanionic bidentate ligand used as a light emitting material may be selected from those known in the art. Non-limited examples of the monoanionic bidentate ligand are described in WO 02/15645 filed by Lamansky et al., which is incorporated herein by reference, 89 to 90 pages. Preferred monoanionic bidentate ligands include acetylacetonate (acac) and picolinate (pic) and derivatives thereof. In the present invention, in terms of stability of complexes and high light emitting quantum efficiency, the monoanionic bidentate ligand is preferably acetylacetonate represented by Formula (PIL-1) and a derivative thereof

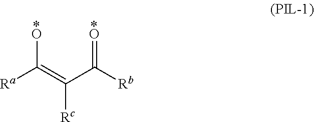

In Formula (PQL-1), each of R^{a} to R^{c} independently represents a hydrogen atom or an alkyl group or an aryl group. * represents a position coordinated to iridium.

Each of the alkyl group represented by R^{a} to R^{c} may independently have a substituent and may be saturated or unsaturated. The substituent of the alkyl group having a substituent may be the aforementioned substituent Z and the substituent Z is preferably a fluorine atom.

The alkyl group represented by R^{a} to R^{c} is preferably an alkyl group having 1 to 8 carbon atoms, more preferably an alkyl group having 1 to 4 carbon atoms, and examples thereof include a methyl group, an ethyl group, a vinyl group, an n-propyl group, an isopropyl group, an isobutyl group, a t-butyl group, an n-butyl group, a cyclopropyl group, a trifluoro methyl group and the like. A methyl group, an ethyl group, an isobutyl group, or a t-butyl group is preferred, a methyl group or a t-butyl group is more preferred, and a methyl group is even more preferred.

Each of the aryl group represented by R^{a} to R^{c} may be independently condensed and may have a substituent. The substituent of the aryl group having a substituent may be the aforementioned substituent Z, and the substituent Z is preferably an alkyl group. The aryl group represented by R^{a} to R^{c} is preferably an aryl group having 6 to 12 carbon atoms, more preferably an aryl group having 6 to 10 carbon atoms, and examples thereof include a phenyl group, a tolyl group and the like. A phenyl group is preferred.

In terms of stability of complexes, each of R^{a} and R^{b} is preferably one of an alkyl group and an aryl group, more preferably an alkyl group.

The alkyl group represented by R^{a} and R^{b} is preferably an alkyl group having 1 to 4 carbon atoms, more preferably any one of a methyl group and a t-butyl group, more preferably a methyl group. R^{a} and R^{b} are preferably identical.

R^{c} is preferably a hydrogen atom.

Hereinafter, specific examples of the compound represented by Formula (PI-1) are given below and the present invention is not limited thereto.

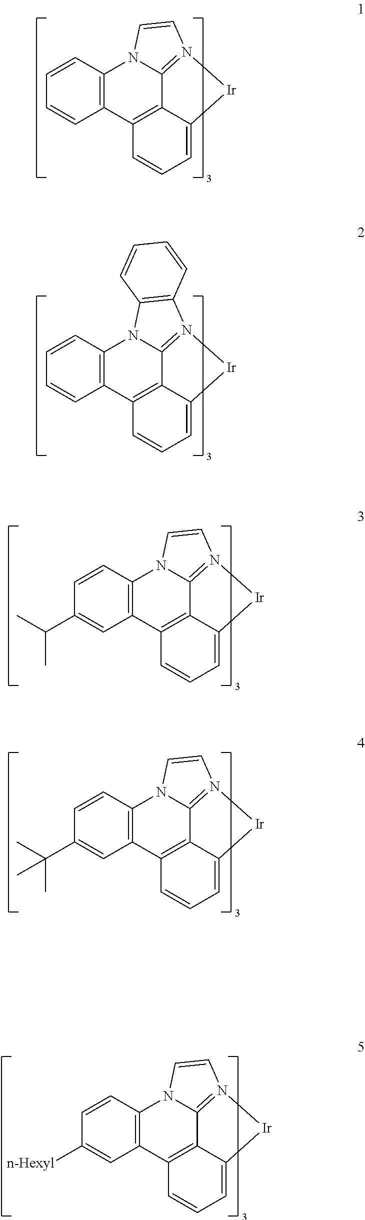

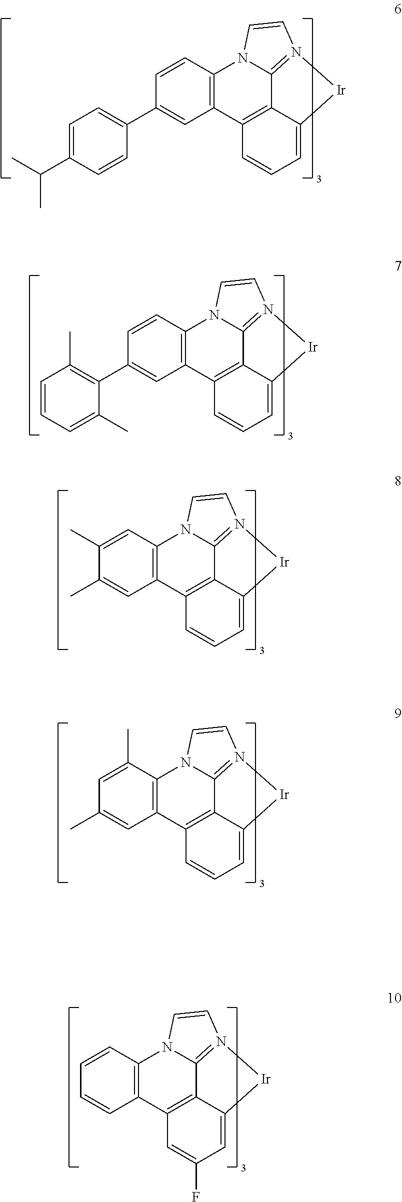

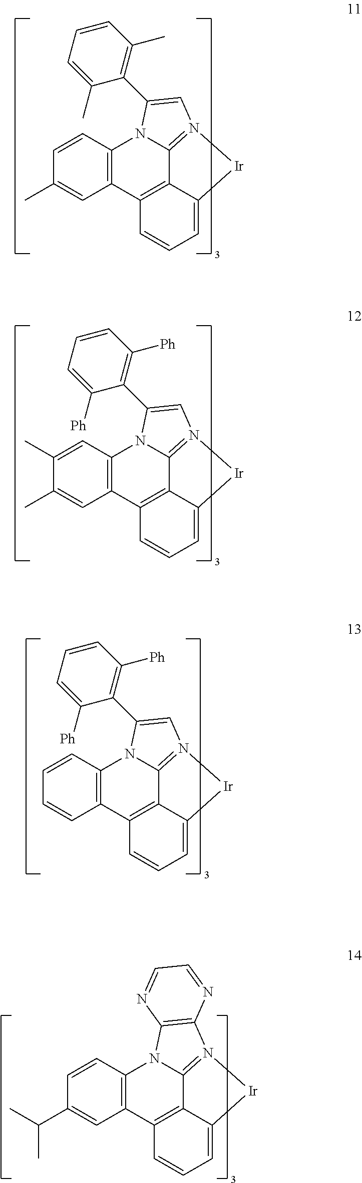

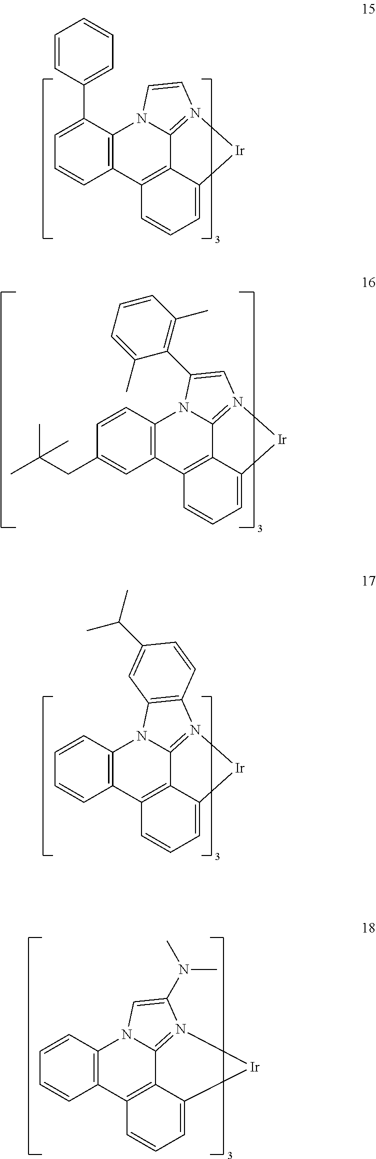

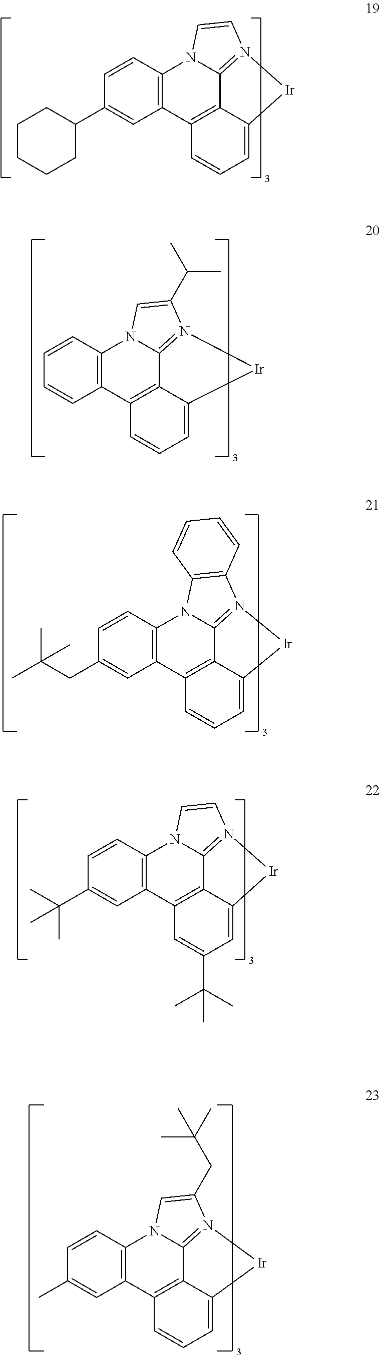

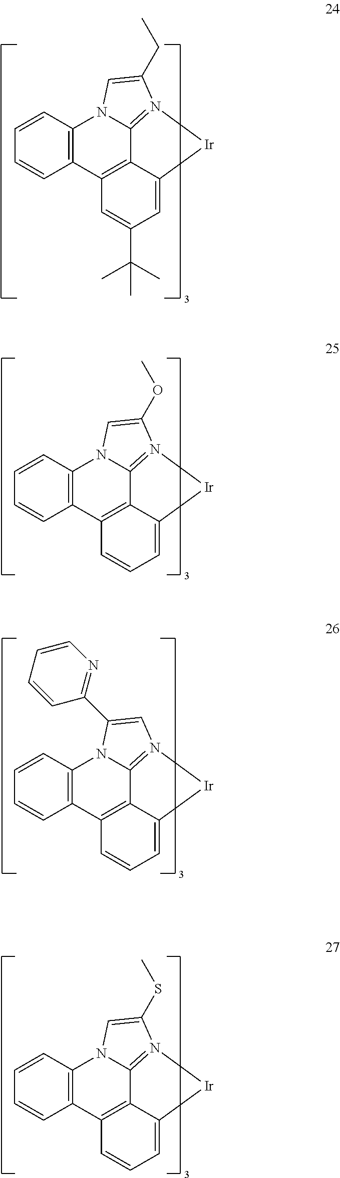

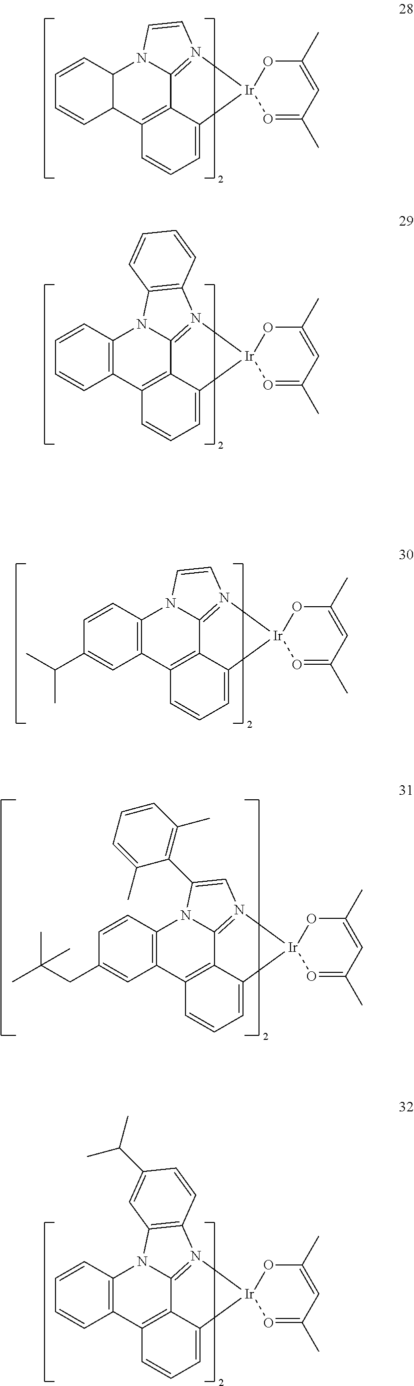

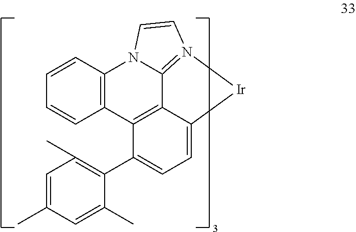

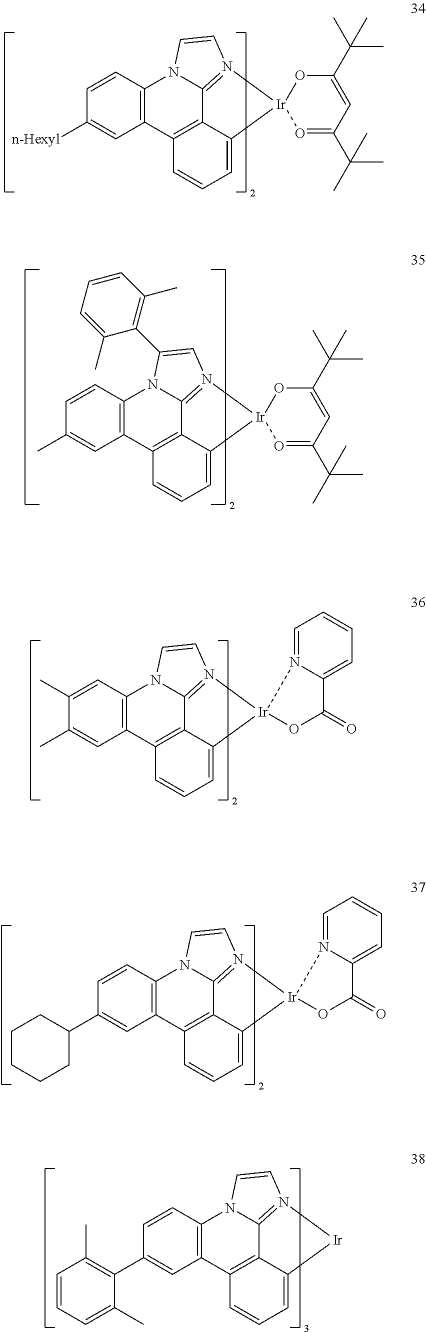

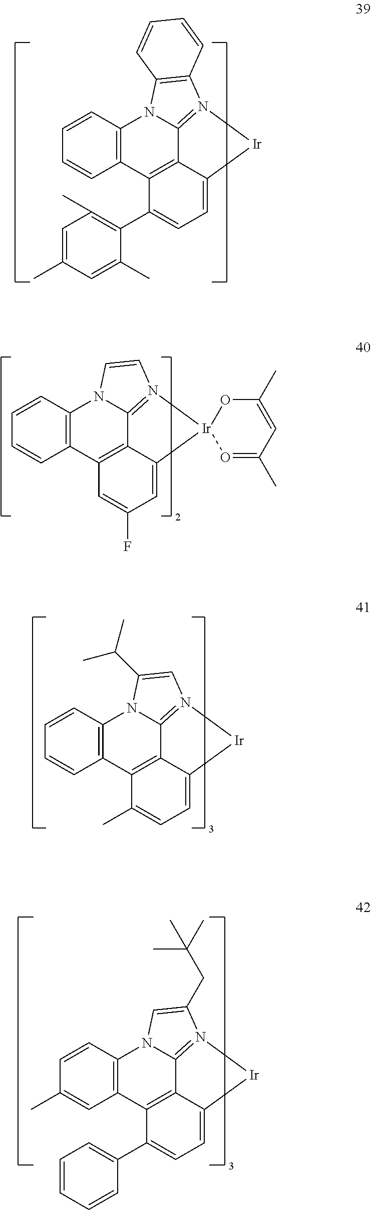

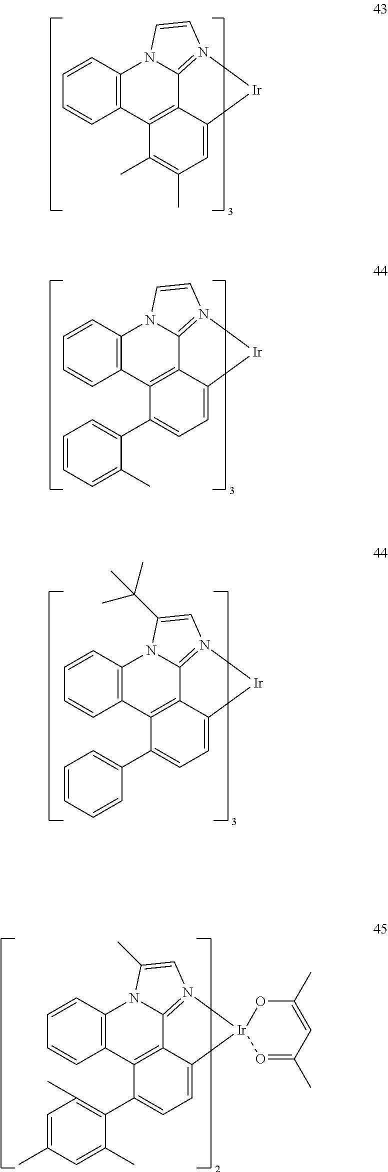

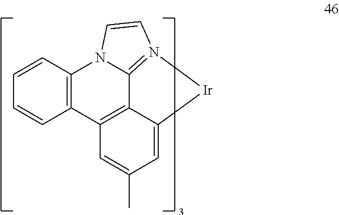

For example, the compounds given as examples of the compound represented by Formula (PI-1) may be synthesized by the methods described in US Patent Application Publication Nos. 2007/0190359 and 2008/0297033. For example, the compound 1 can be synthesized by the method described in page 44, [0104] to page 45, [0107] of US Patent Application Publication No. 2007/0190359.

In the present invention, the compound represented by Formula (PI-1) is contained in the light emitting layer and use thereof is not limited and may be further contained in any one of the organic layer.

In the present invention, in order to further suppress variation in chromaticity after high-temperature driving, a compound represented by Formula (1) or (2) described below and a compound represented by Formula (PI-1) are preferably contained in the light emitting layer.

The compound represented by Formula (PI-1) is preferably contained in an amount of 0.1 to 30% by mass, more preferably 1 to 20% by mass, even more preferably 5 to 15% by mass, with respect to the total mass of the light emitting layer.

[Compound Represented by Formula (1)]

Hereinafter, the compound represented by Formula (1) will be described.

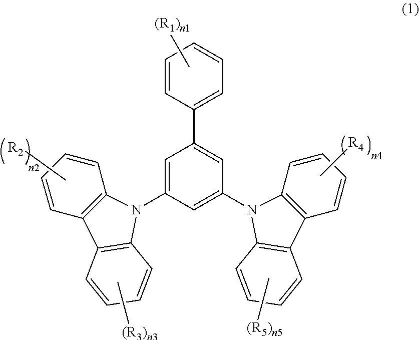

In Formula (1), R₁ represents an alkyl group, an aryl group or a silyl group and may further have a substituent Z. However, there is no case in which R₁ represents a carbazolyl group or a perfluoroalkyl alkyl group. In a case in which R₁ is present in plural, each of a plurality of R₁'s may be the same as or different from every other R₁. In addition, a plurality of R₁'s may be combined together to form an aryl ring which may have a substituent Z.

Each of R₂ to R₅ independently represents an alkyl group, an aryl group, a silyl group, a cyano group or a fluorine atom and may further have a substituent Z. In a case in which each of R₂ to R₅ is present in plural, each of the plurality of R₂'s to the plurality of R₅'s may be the same as or different from every other R₂ to R₅, respectively.

The substituent Z represents an alkyl group, an alkenyl group, an aryl group, an aromatic heterocyclic group, an alkoxy group, a phenoxy group, a fluorine atom, a silyl group, an amino group, a cyano group or a group formed by combination thereof, and the plurality of substituents Z may be combined together to form an aryl group.

n1 represents an integer of 0 to 5.

Each of n2 to n5 independently represents an integer of 0 to 4.

The alkyl group represented by R₁ may have a substituent and may be saturated or unsaturated. The substituent of the alkyl group having a substituent may be the aforementioned substituent Z, and the substituent Z is preferably a fluorine atom. However, there is no case in which the alkyl group represented by R₁ is a perfluoroalkyl alkyl group. The alkyl group represented by R₁ is preferably an alkyl group having 1 to 8 carbon atoms, more preferably an alkyl group having 1 to 6 carbon atoms, even more preferably an alkyl group having 1 to 4 carbon atoms. Examples thereof include a methyl group, an ethyl group, an n-propyl group, an isopropyl group, an n-butyl group, an isobutyl group, a sec-butyl group, a t-butyl group, an n-pentyl group, an isopentyl group, a 2-methylpentyl group, a neopentyl group, a n-hexyl group, a 4-methylpentyl group, a 3-methylpentyl group, a 2-methylpentyl group, a 3,3-dimethylbutyl group, a 2,2-dimethylbutyl group, a 1,1-dimethylbutyl group, a 1,2-dimethylbutyl group, a 1,3-dimethylbutyl group, a 2,3-dimethylbutyl group and the like. Among them, a methyl group, an isopropyl group, a t-butyl group or a neopentyl group is preferred, a methyl group or a t-butyl group is more preferred and a t-butyl group is even more preferred.

The aryl group represented by R₁ may be condensed and have a substituent. The substituent of the aryl group having a substituent may be the aforementioned substituent Z, and the substituent Z is preferably an alkyl group which may be substituted by a fluorine atom, an aryl group, a fluorine atom or a cyano group, more preferably an alkyl group. The aryl group represented by R₁ is preferably an aryl group having 6 to 30 carbon atoms, more preferably an aryl group having 6 to 18 carbon atoms. The aryl group having 6 to 18 carbon atoms is preferably an aryl group having 6 to 18 carbon atoms which may have an alkyl group having 1 to 6 carbon atoms that may be substituted by a fluorine atom, a fluorine atom or a cyano group, more preferably an aryl group having 6 to 18 carbon atoms which may have an alkyl group having 1 to 4 carbon atoms. Examples thereof include a phenyl group, a dimethylphenyl group, a biphenyl group, a terphenyl group, a naphthyl group, a methylnaphthyl group, a t-butylnaphthyl group, an anthranyl group, a phenanthryl group, a chrysenyl group, a cyanophenyl group, a trifluoromethylphenyl group, a fluorophenyl group and the like. Among them, a phenyl group, a dimethylphenyl group, a biphenyl group, a terphenyl group, a naphthyl group, a methylnaphthyl group, or a t-butylnaphthyl group is preferred and a phenyl group, a biphenyl group or a terphenyl group is more preferred.

The silyl group represented by R₁ may have a substituent. The substituent of the silyl group having a substituent may be the aforementioned substituent Z, and the substituent Z is preferably an alkyl group or a phenyl group, more preferably a phenyl group. The silyl group represented by R₁ is preferably a silyl group having 0 to 18 carbon atoms, more preferably a silyl group having 3 to 18 carbon atoms. The silyl group having 3 to 18 carbon atoms is preferably a silyl group having 3 to 18 carbon atoms substituted by an alkyl group having 1 to 6 carbon atoms or a phenyl group, more preferably a silyl group in which all of three hydrogen atoms are substituted by an alkyl group having 1 to 6 carbon atoms or a phenyl group, even more preferably a silyl group substituted by a phenyl group. Examples of the silyl group include a trimethylsilyl group, a triethylsilyl group, a t-butyldimethylsilyl group, a diethylisopropylsilyl group, a dimethylphenylsilyl group, a diphenylmethylsilyl group, a triphenylsilyl group and the like. Among them, a trimethylsilyl group, a dimethylphenylsilyl group or a triphenylsilyl group is preferred and a triphenylsilyl group is more preferred.

In a case in which R₁ is present in plural, each of a plurality of R₁'s may be the same as or different from every other R₁. In addition, the plurality of R₁'s may be combined together to form an aryl ring which may have the aforementioned substituent Z. The substituent Z is preferably an alkyl group or an aryl group, more preferably an alkyl group.

The aryl ring formed by combining a plurality of R₁'s together is preferably an aryl ring having 6 to 30 carbon atoms, more preferably an aryl ring having 6 to 14 carbon atoms, including carbon atoms substituted by the plurality of R₁'s. The formed ring is preferably any one of a benzene ring, a naphthalene ring and a phenanthrene ring, more preferably a benzene ring or a phenanthrene ring, even more preferably a benzene ring. Furthermore, the ring formed by a plurality of R₁'s may be present in a plural. For example, a plurality of R₁'s is combined together to form two benzene rings so that a phenanthrene ring is formed together with the benzene ring to which the plurality of R₁'s are substituted.

In terms of electric charge transporting performance and electric charge-associated stability, R₁ is preferably any one of an alkyl group, an aryl group that may have an alkyl group, a silyl group substituted by an alkyl group or a phenyl group, more preferably an aryl group having 6 to 18 carbon atoms which may have an alkyl group having 1 to 6 carbon atoms, more preferably an aryl group having 6 to 18 carbon atoms which may have an alkyl group having 1 to 4 carbon atoms.

Among them, R₁ is preferably a methyl group, a t-butyl group, a neopentyl group, a unsubstituted phenyl group, a phenyl group substituted by a cyano group, a fluorine atom or a trifluoromethyl group, a biphenyl group, a terphenyl group, a unsubstituted naphthyl group, a naphthyl group substituted by a methyl group or a t-butyl group, a triphenylsilyl group, a benzene ring or a phenanthrene ring formed by combining a plurality of alkyl groups or aryl groups together, more preferably a unsubstituted phenyl group, a biphenyl group or a terphenyl group, more preferably a unsubstituted phenyl group or a terphenyl group.

n1 is preferably an integer of 0 to 4, more preferably an integer of 0 to 3, even more preferably an integer of 0 to 2.

Specific examples and preferred examples of the aryl and silyl groups represented by R₂ to R₅ are the same as specific examples and preferred examples of the aryl and silyl groups represented by R₁.

Examples of the alkyl group represented by R₂ to R₅ include, in addition to examples of the alkyl group represented by R₁, a perfluoroalkyl alkyl group such as trifluoromethyl group. Among them, a methyl group, a trifluoromethyl group, an isopropyl group, a t-butyl group or a neopentyl group is preferred, a methyl group or a t-butyl group is more preferred, and a t-butyl group is even more preferred.

In terms of electric charge transporting performance and electric charge-associated stability, each of R₂ to R₅ is independently preferably any one of an alkyl group, an aryl group, a silyl group substituted by an alkyl group or a phenyl group, a cyano group and a fluorine atom, more preferably any one of an alkyl group having 1 to 6 carbon atoms, an aryl group having 6 to 18 carbon atoms, a silyl group having 3 to 18 carbon atoms substituted by an alkyl group having 1 to 6 carbon atoms or a phenyl group, a cyano group and a fluorine atom, even more preferably any one of an alkyl group having 1 to 4 carbon atoms, an aryl group having 6 to 12 carbon atoms, a silyl group having 3 to 18 carbon atoms substituted by an alkyl group having 1 to 6 carbon atoms or a phenyl group, a cyano group and a fluorine atom.

Among them, each of R₂ to R₅ is independently preferably any one of a methyl group, an isopropyl group, a t-butyl group, a neopentyl group, a trifluoromethyl group, a phenyl group, a dimethylphenyl group, a trimethylsilyl group, a triphenylsilyl group, a fluorine atom and a cyano group, more preferably a t-butyl group, a phenyl group, a trimethylsilyl group, a triphenylsilyl group and a cyano group, even more preferably any one of a t-butyl group, a phenyl group, a triphenylsilyl group and a cyano group.

Each of n2 to n5 is independently preferably an integer of 0 to 2, more preferably 0 or 1. In a case in which a substituent is incorporated into a carbazole structure, 3- and 6-positions of the carbazole structure are reactive positions and the substituent is preferably incorporated into these positions in terms of easy synthesis and improvement in chemical stability.

The compound represented by Formula (1) is more preferably represented by Formula (2).

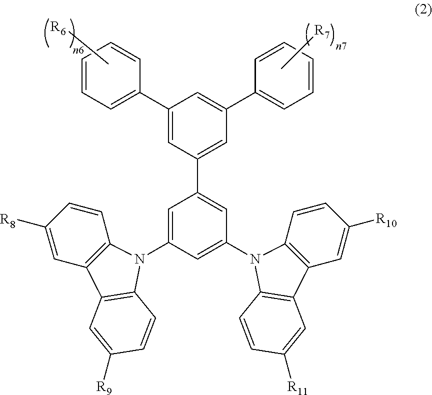

In Formula (2), each of R₆ and R₇ independently represents an alkyl group which may have a substituent Z, an aryl group which may have an alkyl group, a cyano group or a fluorine atom. In a case in which each of R₆ and R₇ is present in plural, each of the plurality of R₆'s and the plurality of R₇'s may be the same as or different from every other R₆ and R₇, respectively. In addition, each of a plurality of R₆'s and a plurality of R₇'s may be combined together to form an aryl ring that may have a substituent Z.

Each of n6 and n7 independently represents an integer of 0 to 5.

Each of R₈ to R₁₁ independently represents a hydrogen atom, an alkyl group which may have a substituent Z, an aryl group which may have an alkyl group, a silyl group which may have a substituent Z, a cyano group or a fluorine atom.

The substituent Z represents an alkyl group, an alkenyl group, an aryl group, an aromatic heterocyclic group, an alkoxy group, a phenoxy group, a fluorine atom, a silyl group, an amino group, a cyano group or a group formed by combination thereof and a plurality of substituents Z may be combined together to form an aryl group.

The alkyl group represented by R₆ and R₇ may have a substituent and may be saturated or unsaturated. The substituent of the alkyl group having a substituent may be the aforementioned substituent Z and the substituent Z is preferably a fluorine atom.

The alkyl group represented by R₆ and R₇ is preferably an alkyl group having 1 to 6 carbon atoms, more preferably an alkyl group having 1 to 4 carbon atoms. Specific examples and preferred examples of the alkyl group represented by R₆ and R₇ are the same as specific examples and preferred examples of the alkyl group represented by R₂ to R₅.

In the aryl group which may have an alkyl group represented by R₆ and R₇, the alkyl group is preferably an alkyl group having 1 to 6 carbon atoms, more preferably an alkyl group having 1 to 4 carbon atoms. Specific examples and preferred examples of the alkyl group are the same as specific examples and preferred examples of the alkyl group represented by R₂ to R₅.

In the aryl group which may have an alkyl group, represented by R₆ and R₇, the aryl group is preferably an aryl group having 6 to 18 carbon atoms, more preferably an aryl group having 6 to 12 carbon atoms. Examples of the aryl group include a phenyl group, a biphenyl group, a terphenyl group, a naphthyl group, an anthranyl group, a phenanthryl group, a chrysenyl group and the like. Among them, a phenyl group, a biphenyl group, a terphenyl group or a naphthyl group is preferred, and a phenyl group, a biphenyl group or a terphenyl group is more preferred.

The aryl group which may have an alkyl group represented by R₆ and R₇ is preferably an unsubstituted aryl group.

Examples of the aryl group which may have an alkyl group represented by R₆ and R₇ include a phenyl group, a dimethylphenyl group, a t-butylphenyl group, a biphenyl group, a terphenyl group, a naphthyl group, a methylnaphthyl group, a t-butylnaphthyl group, an anthranyl group, a phenanthryl group, a chrysenyl group and the like. Among them, a phenyl group, a t-butylphenyl group or a biphenyl group is preferred and a phenyl group is more preferred.

In a case in which each of R₆ and R₇ are present in plural, each of the plurality of R₆'s and the plurality of R₇'s may be the same as or different from every other R₆ and R₇, respectively. In addition, each of a plurality of R₆'s and a plurality of R₇'s may be combined together to form an aryl ring that may have a substituent Z. The substituent Z is preferably an alkyl group or an aryl group, more preferably an alkyl group.

The aryl group formed by combining a plurality of R₆'s and a plurality of R₇'s together is preferably an aryl ring having 6 to 30 carbon atoms, more preferably an aryl ring having 6 to 14 carbon atoms, even more preferably an aryl ring having 6 to 14 carbon atom which may have an alkyl group having 1 to 4 carbon atoms, including carbon atoms to which the plurality of R₆'s and the plurality of R₇'s are substituted. The formed ring is preferably any one of a benzene ring, a naphthalene ring and a phenanthrene ring, which may have an alkyl group having 1 to 4 carbon atoms, more preferably a benzene ring which may have an alkyl group having 1 to 4 carbon atoms, and examples thereof include a benzene ring, a benzene ring substituted by a t-butyl group and the like. Furthermore, the ring formed by combining a plurality of R₆'s and a plurality of R₇'s together may be present in plural. For example, each of a plurality of R₆'s or a plurality of R₇'s are combined together to form two benzene rings so that a phenanthrene ring is formed together with the benzene ring to which the plurality of R₆'s or the plurality of R₇'s are substituted.

In terms of electric charge transporting performance and electric charge-associated stability, R₆ and R₇ are preferably any one of an alkyl group having 1 to 6 carbon atoms, an aryl group having 6 to 18 carbon atoms which may have an alkyl group having 1 to 6 carbon atoms, a cyano group and a fluorine atom, more preferably any one of an alkyl group having 1 to 4 carbon atoms, an aryl group having 6 to 12 carbon atoms which may have an alkyl group having 1 to 4 carbon atoms, a cyano group and a fluorine atom. In terms of electric charge transporting performance and electric charge-associated stability, each of R₆ and R₇ independently preferably represents an alkyl group or an aryl group which may have an alkyl group.

Among them, each of R₆ and R₇ independently preferably represents a methyl group, a trifluoromethyl group, a t-butyl group, a unsubstituted phenyl group, a phenyl group substituted by a t-butyl group, a biphenyl group, a cyano group, a fluorine atom, a unsubstituted benzene ring formed by combining a plurality of alkyl groups together or a benzene ring substituted by a t-butyl group, more preferably a methyl group, a trifluoromethyl group, unsubstituted phenyl group, a cyano group, a fluorine atom, a unsubstituted benzene ring formed by combining a plurality of alkyl groups together or a benzene ring substituted by a t-butyl group, most preferably a unsubstituted phenyl group.

Each of n6 and n7 independently preferably represents an integer of 0 to 4, more preferably an integer of 0 to 2, even more preferably 0 or 1.

The alkyl group represented by R₈ to R₁₁ may have a substituent and may be saturated or unsaturated. The substituent of the alkyl group having a substituent may be the aforementioned substituent Z and the substituent Z is preferably a fluorine atom.

The alkyl group represented by R₈ to R₁₁ is preferably an alkyl group having 1 to 6 carbon atoms, more preferably an alkyl group having 1 to 4 carbon atoms. Specific examples and preferred examples of the alkyl group represented by R₈ to R₁₁ are the same as specific examples and preferred examples of the alkyl group represented by R₂ to R₅.

The aryl group which may have an alkyl group represented by R₈ to R₁₁ is preferably an aryl group having 6 to 18 carbon atoms which may have an alkyl group having 1 to 6 carbon atoms, more preferably an aryl group having 6 to 12 carbon atoms which may have an alkyl group having 1 to 4 carbon atoms.

Specific examples and preferred examples of the aryl group which may have the alkyl group represented by R₈ to R₁₁ are the same as specific examples and preferred examples of the aryl group which may have the alkyl group represented by R₆ and R₇.

The silyl group represented by R₈ to R₁₁ may have a substituent. The substituent of the silyl group having a substituent may be the aforementioned substituent Z and the substituent Z is preferably an alkyl group or a phenyl group, more preferably a phenyl group. The silyl group represented by R₈ to R₁₁ is preferably a silyl group having 3 to 18 carbon atoms, and specific examples and preferred examples of a silyl group having 3 to 18 carbon atoms represented by R₈ to R₁₁ are the same as specific examples and preferred examples of the silyl group having 3 to 18 carbon atoms of the silyl group represented by R₁.

In terms of electric charge transporting performance and electric charge-associated stability, each of R₈ to R₁₁ is independently preferably any one of a hydrogen atom, an alkyl group, an aryl group which may have an alkyl group, a silyl group substituted by an alkyl group or a phenyl group, a cyano group and a fluorine atom, more preferably any one of a hydrogen atom, an alkyl group having 1 to 6 carbon atoms, an aryl group having 6 to 18 carbon atoms which may have an alkyl group having 1 to 6 carbon atoms, a silyl group having 3 to 18 carbon atoms substituted by an alkyl group having 1 to 6 carbon atoms or a phenyl group, a cyano group and a fluorine atom, more preferably any one of a hydrogen atom, an alkyl group having 1 to 4 carbon atoms, an aryl group having 6 to 12 carbon atoms which may have an alkyl group having 1 to 4 carbon atoms, a silyl group having 3 to 18 carbon atoms substituted by an alkyl group having 1 to 6 carbon atoms or a phenyl group, a cyano group and a fluorine atom.

Among them, each of R₈ to R₁₁ is independently preferably any one of a hydrogen atom, a methyl group, an isopropyl group, a t-butyl group, a neopentyl group, a trifluoromethyl group, a phenyl group, a dimethylphenyl group, a trimethylsilyl group, a triphenylsilyl group, a fluorine atom and a cyano group, more preferably a hydrogen atom, a t-butyl group, a phenyl group, a trimethylsilyl group, a triphenylsilyl group and a cyano group, more preferably any one of a hydrogen atom, a t-butyl group, a phenyl group, a triphenylsilyl group and a cyano group.

The compound represented by Formula (1) or (2) is most preferably composed of only a carbon atom, a hydrogen atom and a nitrogen atom.

The compound represented by Formula (1) or (2) preferably has a glass transition temperature (Tg) of 80° C. to 400° C., more preferably 100° C. to 400° C., even more preferably 120° C. to 400° C.

In a case in which the compound of Formula (1) or (2) has a hydrogen atom, it contains an isotope (such as heavy hydrogen atom). In this case, all hydrogen atoms in the compound may be substituted by the isotope and some thereof may be a compound containing an isotope as a mixture.

Hereinafter, specific examples of the compound represented by Formula (1) or (2) are given and the present invention is not limited thereto.

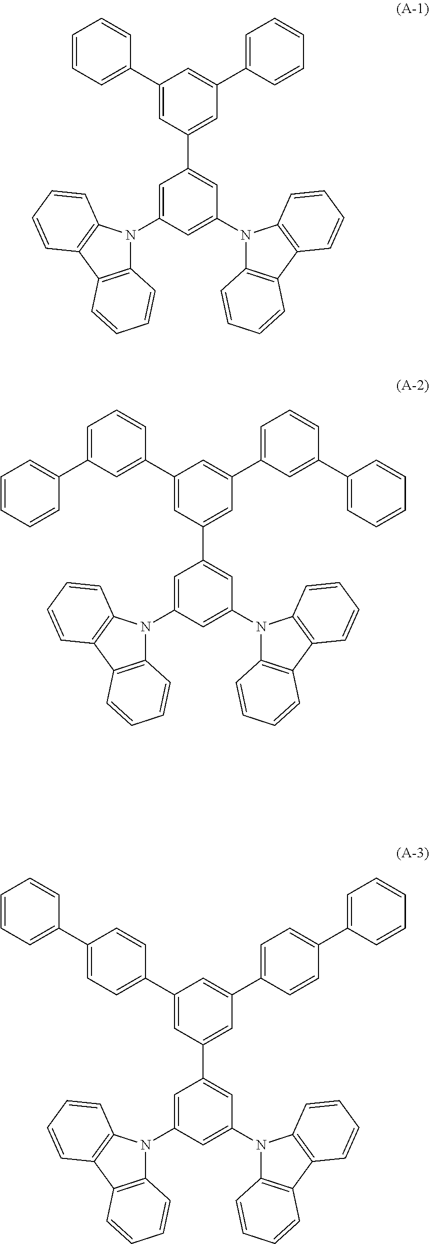

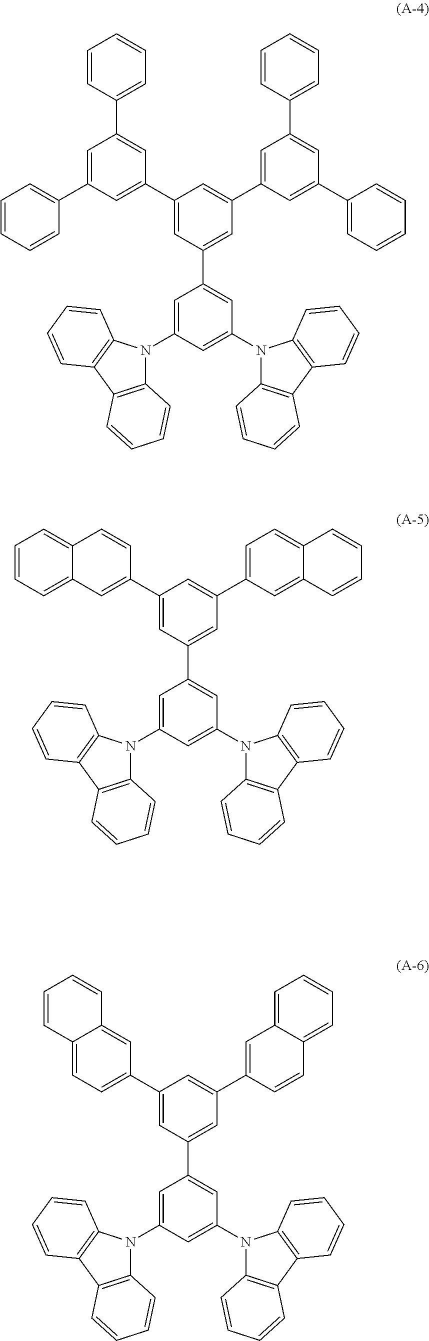

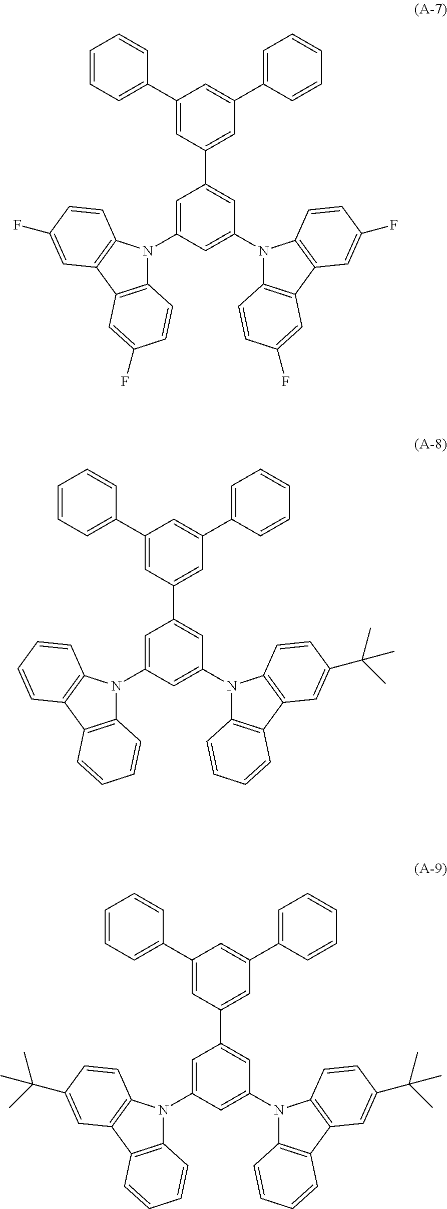

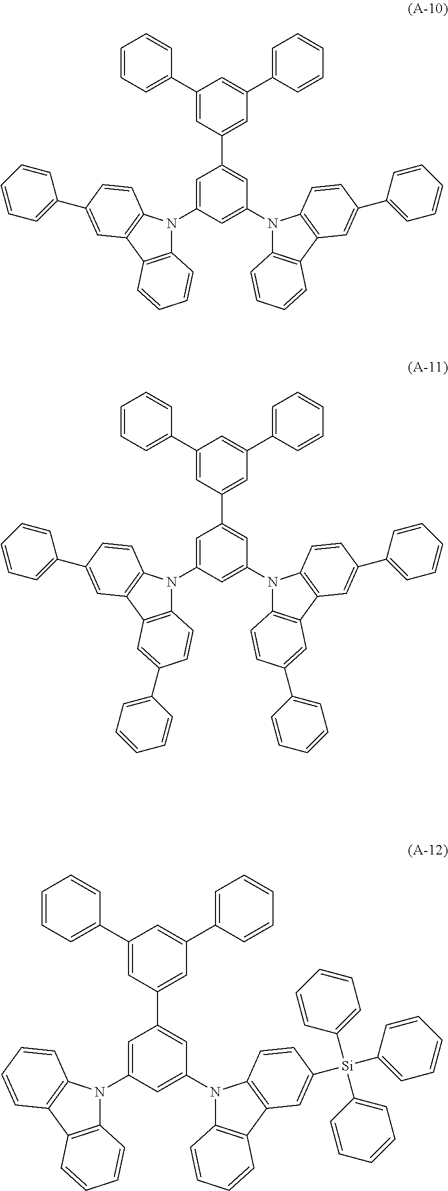

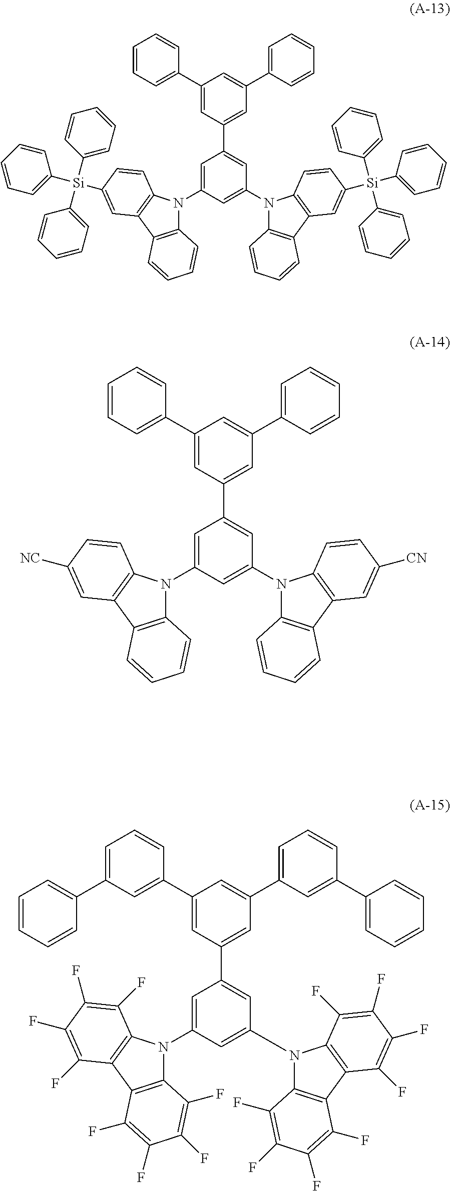

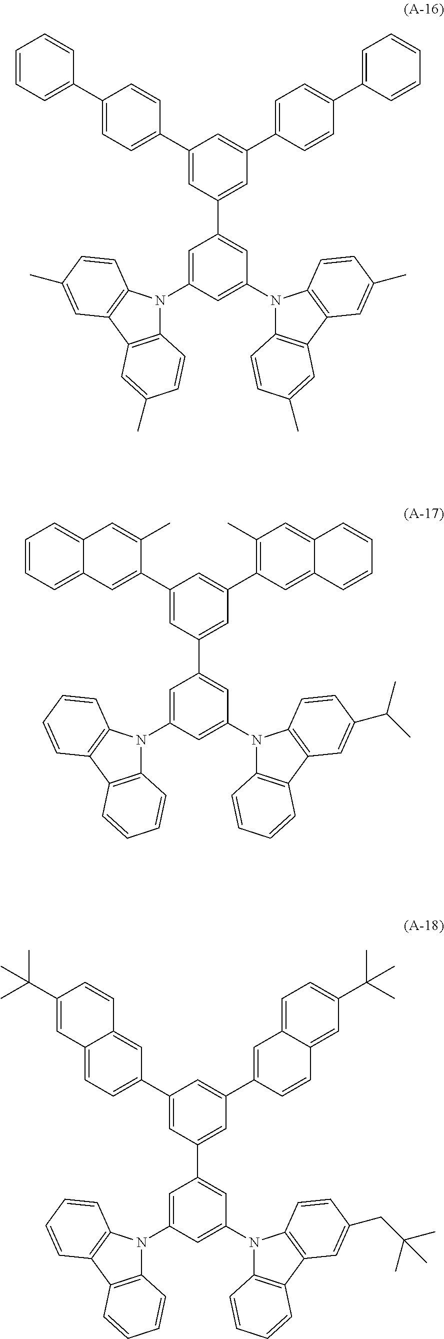

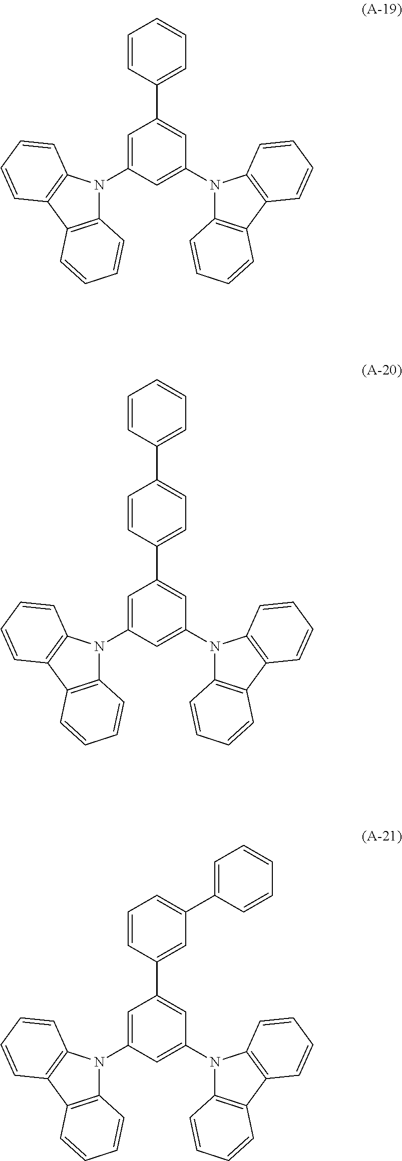

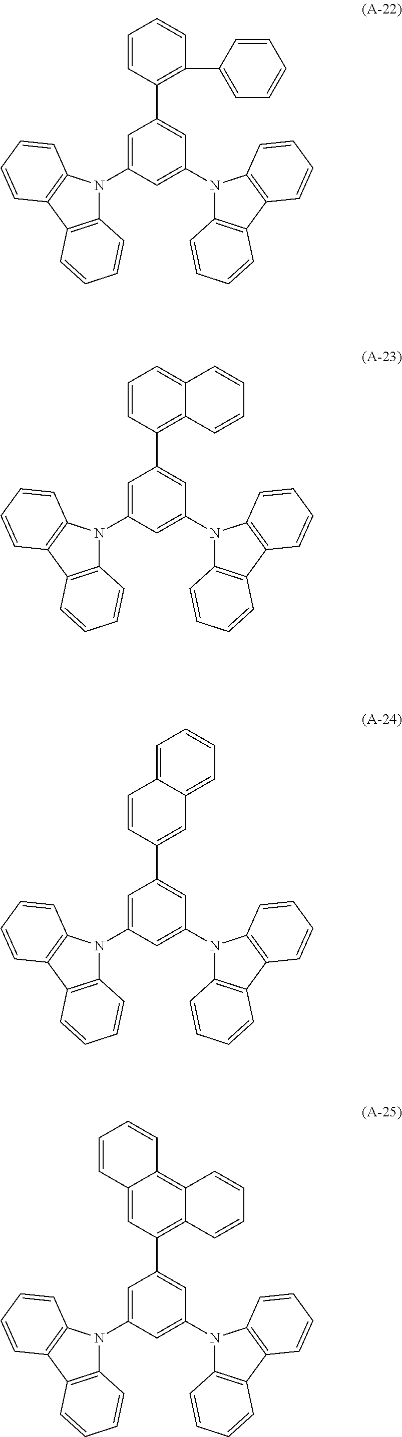

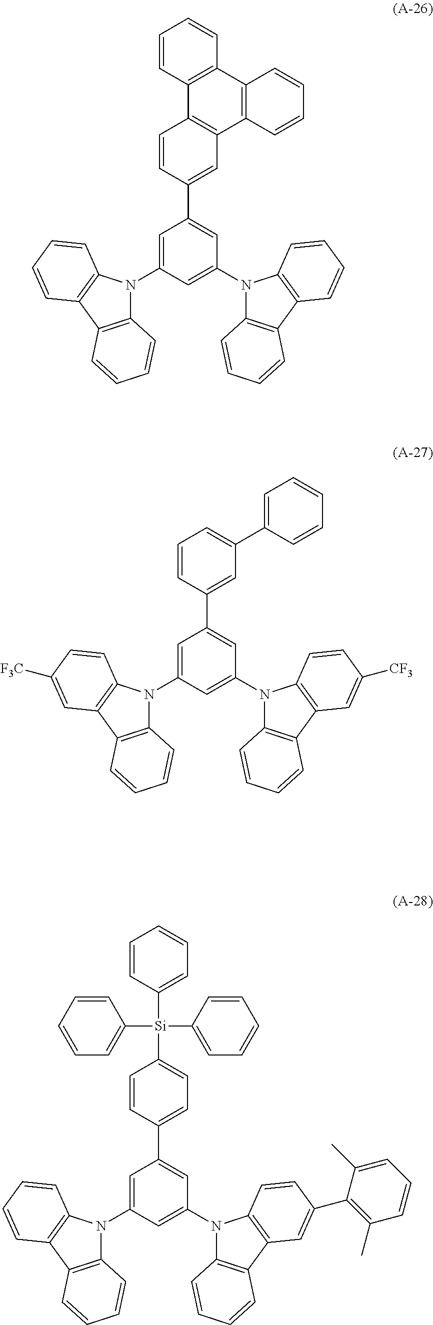

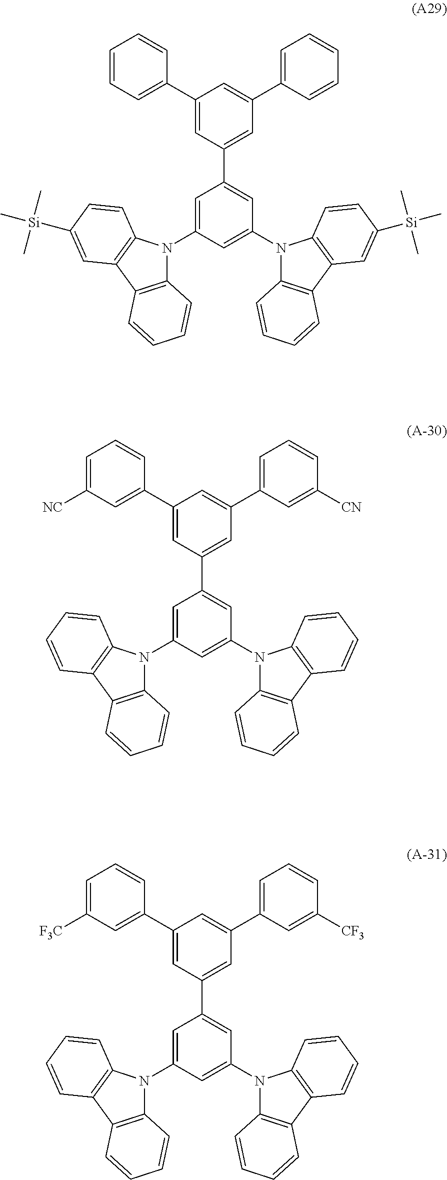

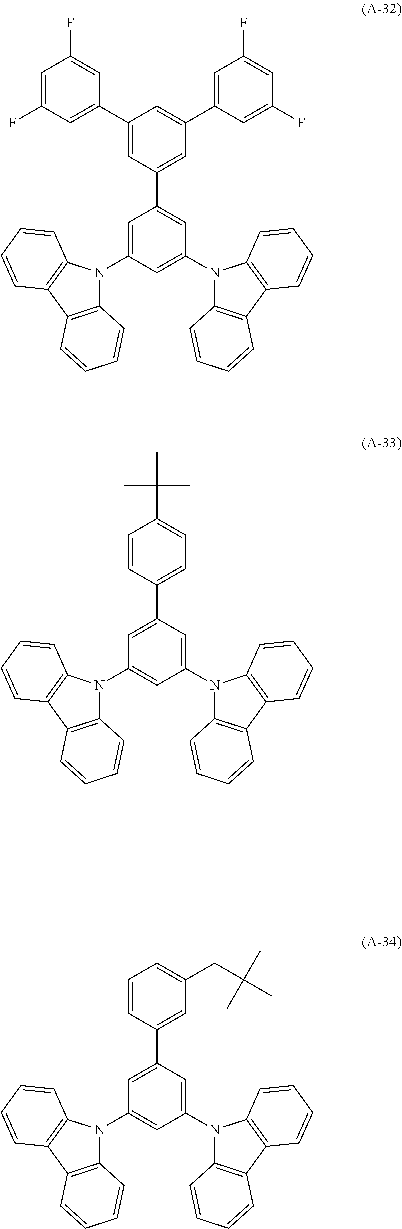

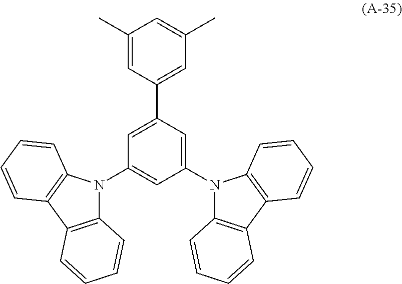

The compound exemplified as the compound represented by Formula (1) or (2) is synthesized based on WO 2004/074399 or the like. For example, the compound (A-1) may be synthesized by a method described in WO 2004/074399, page 52, line 22 to page 54, line 15.

In the present invention, use of the compound represented by Formula (1) or (2) is not limited and may be contained in any layer of the organic layer. The layer into which the compound represented by Formula (1) or (2) is incorporated is preferably one or more of a light emitting layer, a layer between a light emitting layer and a cathode and a layer between a light emitting layer and an anode, more preferably one or more of a light emitting layer, a hole injection layer, a hole transporting layer, an electron transporting layer, an electron injection layer, an exciton block layer and an electric charge block layer.

In the present invention, in order to further suppress variation in chromaticity after driving at high temperatures, the compound represented by Formula (1) or (2) is preferably contained in the light emitting layer or any one adjacent layer to the light emitting layer, more preferably contained in the light emitting layer. In addition, the compound represented by Formula (1) or (2) may be contained in both the light emitting layer and the layer adjacent thereto.

When the compound represented by Formula (1) or (2) is contained in the light emitting layer, the compound represented by Formula (1) or (2) of the present invention is contained in an amount of 0.1 to 99% by mass, more preferably 1 to 95% by mass, even more preferably 10 to 95% by mass, with respect to the total mass of the light emitting layer. When the compound represented by Formula (1) or (2) is further contained, in addition to the light emitting layer, in the other layer, the compound is preferably contained in an amount of 70 to 100% by mass, more preferably 85 to 100% by mass, with respect to the total mass of the layer.

[Light Emitting Layer Containing Compound Represented by Formula (PI-1) and Compound Represented by Formula (1) or (2)]

The present invention is also directed to a light emitting layer containing a compound represented by Formula (PI-1) and a compound represented by Formula (1) or (2). The light emitting layer of the present invention may be used for an organic electroluminescence device.

[Composition Containing Compound Represented by Formula (PI-1) and Compound Represented by Formula (1) or (2)]

The present invention is also directed to a composition containing a compound represented by Formula (PI-1) and a compound represented by Formula (1) or (2).

In the composition of the present invention, the content of the compound represented by Formula (PI-1) is preferably 1 to 40% by mass, more preferably 3 to 20% by mass, with respect to the total solid content of the composition.

In the composition of the present invention, the content of the compound represented by Formula (1) or (2) is preferably 50 to 97% by mass, more preferably 70 to 90% by mass, with respect to the total solid content of the composition.

The component which may be further contained in the composition of the present invention may be an organic or inorganic substance. Examples of useful organic substances include the host material, a fluorescent light emitting material, a phosphorescent light emitting material, a hydrocarbon substance. An organic layer of an organic electroluminescence device can be formed using the composition of the present invention by a dry-type film formation method such as a deposition method or a sputtering method, or a wet-type film formation method such as a transfer method or a printing method.

[Organic Electroluminescence Device]

The device of the present invention will be described in more detail.

The organic electroluminescence device of the present invention is an organic electroluminescence device that includes a pair of electrodes disposed on a substrate, and at least one organic layer including a light emitting layer disposed between the electrodes. The light emitting layer contains at least one compound represented by Formula (PI-1) and any one of the at least one organic layer contains at least one compound represented by Formula (1).

In the organic electroluminescence device of the present invention, the light emitting layer is an organic layer and may further have a plurality of organic layers.

In terms of characteristics of the device, at least one electrode of the anode and cathode is preferably transparent or semitransparent.

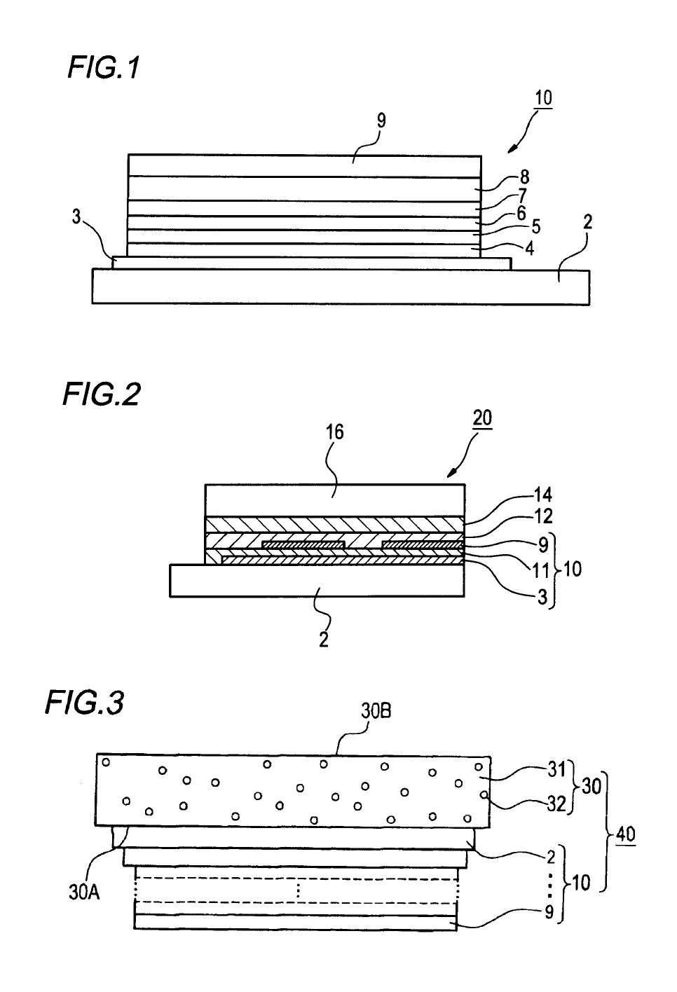

FIG. 1 illustrates an example of a configuration of the organic electroluminescence device. As shown in FIG. 1, the organic electroluminescence device 10 according to the present invention has a structure in which a light emitting layer 6 is interposed between an anode 3 and a cathode 9 on a substrate 2. Specially, a hole injection layer 4, a hole transporting layer 5, a light emitting layer 6, a hole block layer 7 and an electron transporting layer 8 are laminated in this order between the anode 3 and the cathode 9.

<Configuration of Organic Layer>

The configuration of layer constituting the organic layer is not particularly limited and may be suitably selected depending on application and purpose of the organic electroluminescence device. The organic layer is preferably formed on a transparent electrode or a semitransparent electrode. In this case, the organic layer is formed on the front surface or one surface of the transparent electrode or the semitransparent electrode.

The shape, size and thickness of organic layer are not particularly limited and can be suitably selected depending on the purpose.

Specific examples of the specific layer configuration are given below and the present invention is not limited thereto.

Anode/hole transporting layer/light emitting layer/electron transporting layer/cathode,

Anode/hole transporting layer/light emitting layer/block layer/electron transporting layer/cathode,

Anode/hole transporting layer/light emitting layer/block layer/electron transporting layer/electron injection layer/cathode,

Anode/hole injection layer/hole transporting layer/light emitting layer/block layer/electron transporting layer/cathode,

Anode/hole injection layer/hole transporting layer/light emitting layer/block layer/electron transporting layer/electron injection layer/cathode.

The device configuration, substrate, cathode and anode of the organic electroluminescence device are for example described in the pamphlet of Japanese Patent Publication No. 2008-270736 in detail and the contents described in the pamphlet may be applied to the present invention.

<Substrate>

The substrate used in the present invention is preferably a substrate which does not scatter or decrease light emitted from an organic layer. The organic material preferably exhibits superior heat resistance, dimensional stability, solvent resistance, electrical insulating property and processability.

<Anode>

Any anode may be used so long as it serves as an electrode supplying holes into an organic layer and the shape, structure and size thereof are not particularly limited and may be suitably selected from known electrode material depending on the application and purpose of luminescence device. As mentioned above, the anode is commonly disposed as a transparent anode.

<Cathode>

Any cathode may be used so long as it serves as an electrode supplying electrons into the organic layer and the shape, structure and size thereof are not particularly limited and may be suitably selected from known electrode material depending on the application and purpose of luminescence device. As mentioned above, the anode is commonly disposed as a transparent anode.

The contents of the substrate, anode, cathode described in the paragraphs [0070] to of Japanese Patent Publication No. 2008-270736 may be applied to the present invention.

<Organic Layer>

The organic layer of the present invention will be described.

—Formation of Organic Layer—

In the organic electroluminescence device of the present invention, each organic layer may be preferably formed by a dry-type film formation method such as a deposition method or a sputtering method, or a solution coating process such as a transfer method, a printing method, a spin coating method, or a bar coating method. At least one layer of the organic layer is preferably formed by a solution coating process.

(Light Emitting Layer)

<Light Emitting Material>

The light emitting material of the present invention is preferably a compound represented by Formula (PI-1).

The light emitting material of the light emitting layer is contained in an amount of 0.1% by mass to 50% by mass, with respect to the total mass of the compound constituting the light emitting layer in the light emitting layer. The content is preferably 1% by mass to 50% by mass, more preferably 2% by mass to 40% by mass, in terms of durability and external quantum efficiency.

The thickness of the light emitting layer is not particularly limited, and is generally preferably 2 nm to 500 nm, more preferably 3 nm to 200 nm, even more preferably 5 nm to 100 nm, in terms of external quantum efficiency.

In the device of the present invention, the light emitting layer may be composed of only a light emitting material and composed of a mixture of a host material and a light emitting material. The light emitting material may be a fluorescent light emitting material or a phosphorescent light emitting material. The dopant may be one or more types. The host material is preferably an electric charge transporting material. The host material may be one or more types. For example, the host material is composed of a combination of an electron transporting host material and a hole transporting host material. Furthermore, the light emitting layer may contain a material that does not have electric charge transporting property and does not emit light. In the device of the present invention, the light emitting layer preferably uses a compound represented by Formula (1) or (2) as a host material and a compound represented by Formula (PI-1) as a light emitting material.

In addition, the light emitting layer may be a monolayer or a multilayer including two or more layers. When the light emitting layer is present in plural, the compound represented by Formula (1) or (2) and the compound represented by (PI-1) may be also contained in the light emitting layer including two or more layers. In addition, respective light emitting layers may emit light having different colors.

<Host Material>

The host material used in the present invention is preferably a compound represented by Formula (1) or (2).

The compound represented by Formula (1) or (2) is a compound capable of transporting two electric charges of holes and electrons. By combining compound represented by Formula (1) or (2) with the compound represented by Formula (PI-1), it is possible to prevent the balance between hole and electron transporting properties in the light emitting layer from being changed by exterior environment such as temperature or electric field. As a result, it is possible to improve driving durability although the compound has a carbazole group. Furthermore, it is possible to inhibit color variation after driving at a high temperature.

The host material used in the present invention may contain the following compound. Examples of the host material include pyrole, indole, carbazole (such as CBP(4,4′-di(9-carbazolyl)biphenyl)), azeindole, azecarbazole, triazole, oxazole, oxadiazole, pyrazole, imidazole, thiophene, polyarylalkane, pyrazolene, pyrazolone, phenylene diamine, arylamine, amino-substituted kalcone, styryl anthracene, fluorenone, hydrazone, stilbene, silazane, aromatic tertiary amine compounds, styrylamine compounds, porphyrin-based compounds, polysilane-based compounds, poly(N-vinylcarbazole), aniline-based copolymers, thiophene oligomers, conductive polymer oligomers such as polythiophene, organic silane, carbon films, pyridine, pyrimidine, triazine, imidazole, pyrazole, triazole, oxazole, oxadiazole, fluorenone, anthraquinodimethane, anthrone, diphenylquinone, thiopyran dioxide, carbodiimide, fluorenylidene methane, distyrylpyrazine, fluorine-substituted aromatic compounds, heterocyclic ring tetracarboxylic anhydrides such as naphthalene perylene, phthalocyanine, metal complexes or metal phthalocyanine of 8-quinolinol derivatives, various metal complexes and derivative thereof (may have a substituent or a condensed ring) represented by metal complexes having benzoxazole or benzothiazole as a ligand and the like.

In the light emitting layer of the present invention, the host material (also containing the compound represented by Formula (1) or (2)) having the least triplet excited energy (T₁ energy) higher than T₁ energy of the phosphorescent light emitting material is preferred in terms of color purity, light emitting efficiency and driving durability.

In addition, the content of host compound in the present invention is not particularly limited and is preferably 15% by mass to 98% by mass, with respect to the total mass of the compound constituting the light emitting layer, in terms of light emitting efficiency and driving voltage.

(Fluorescent Light Emitting Material)

Examples of the fluorescent light emitting material that can be used for the present invention include benzoxazole derivatives, benzoimidazole derivatives, benzothiazole derivatives, styrylbenzene derivatives, polyphenyl derivatives, diphenyl butadiene derivatives, tetraphenyl butadiene derivatives, naphthalimide derivatives, coumarin derivatives, condensed aromatic compounds, perinone derivatives, oxadiazole derivatives, oxazine derivatives, aldazine derivatives, pyrralidine derivatives, cyclopentadiene derivatives, bisstyryl anthracene derivatives, quinacridone derivatives, pyrrolopyridine derivatives, thiadiazolepyridine derivatives, cyclopentadiene derivatives, styrylamine derivatives, diketopyrrolopyrrole derivatives, aromatic dimethylidine compounds, various complexes represented by complexes of 8-quinolinol derivatives or complexes of pyrromethene derivatives, polymer compounds such as polythiophene, polyphenylene, polyphenylene vinylene, compounds such as organic silane derivatives and the like.

(Phosphorescent Light Emitting Material)

Examples of the phosphorescent light emitting material that can be used in the present invention include, in addition to the compound represented by Formula (PI-1), phosphorescent light emitting compounds described in Patent Documents such as U.S. Pat. No. 6,303,238B1, U.S. Pat. No. 6,097,147, WO 00/57676, WO 00/70655, WO 01/08230, WO 01/39234A2, WO 01/41512A1, WO 02/02714A2, WO 02/15645A1, WO 02/44189A1, WO 05/19373A2, JP-A-2001-247859, JP-A-2002-302671, JP-A-2002-117978, JP-A-2003-133074, JP-A-2002-235076, JP-A-2003-123982, JP-A-2002-170684, EP1211257, JP-A-2002-226495, JP-A-2002-234894, JP-A-2001-247859, JP-A-2001-298470, JP-A-2002-173674, JP-A-2002-203678, JP-A-2002-203679, JP-A-2004-357791, JP-A-2006-256999, JP-A-2007-19462, JP-A-2007-84635, JP-A-2007-96259. Among them, more preferred light emitting materials include Ir complexes, Pt complexes, Cu complexes, Re complexes, W complexes, Rh complexes, Ru complexes, Pd complexes, Os complexes, Eu complexes, Tb complexes, Gd complexes, Dy complexes and Ce complexes. Particularly preferred light emitting materials include Ir complexes, Pt complexes, and Re complexes. Among them, Ir complexes, Pt complexes or Re complexes containing at least one coordination method of metal-carbon bonds, metal-nitrogen bonds, metal-oxygen bonds and metal-sulfur bonds are preferred. Furthermore, in terms of light emitting efficiency, driving durability and chromaticity, Ir complexes, Pt complexes or Re complexes containing multi-dentate ligands of three or more dentates are particularly preferred.

The content of the phosphorescent light emitting material that can be used in the present invention (compound represented by Formula (PI-1) and/or phosphorescent light emitting material used in conjunction therewith) is 0.1% by mass to 50% by mass, more preferably 0.3% by mass to 40% by mass, most preferably 0.5% by mass to 30% by mass, with respect to the total mass of the light emitting layer. In particular, when the content is 0.5% by mass to 30% by mass, chromaticity of light emission of the organic electroluminescence device hardly depends on the concentration of added phosphorescent light emitting material.

Most preferably, the organic electroluminescence device of the present invention contains an amount of 0.5 to 30% by mass of the at least one of the compound (PI-1) (Compound represented by Formula (PI-1)), with respect to the total mass of the light emitting layer.

(Electric Charge Transporting Layer)

The electric charge transporting layer refers to a layer in which electric charges are moved when a voltage is applied to an organic electroluminescence device. Specific examples of the electric charge transporting layer include a hole injection layer, a hole transporting layer, an electron block layer, a light emitting layer, a hole block layer, an electron transporting layer, an electron injection layer and the like. Preferred examples include a hole injection layer, a hole transporting layer, an electron block layer and a light emitting layer. When the electric charge transporting layer formed by a coating method is a hole injection layer, a hole transporting layer, an electron block layer or a light emitting layer, an organic electroluminescence device that is cheap and has high efficiency can be produced. In addition, the electric charge transporting layer is more preferably a hole injection layer, a hole transporting layer or an electron block layer.

—Hole Injection Layer, Hole Transporting Layer—

The hole injection layer and hole transporting layer are layers that have the ability of transporting holes from an anode or the side of the anode to a cathode side.

The hole injection layer preferably contains an electron accepting dopant. When the electron accepting dopant is contained in the hole injection layer, there are effects such as improvement of hole injection property, deterioration in driving voltage and improvement in efficiency.

Any organic or inorganic material may be used as the electron accepting dopant so long as it can extract electrons from a doped material and produce cations. Examples of the material include benzoquinone or derivatives thereof and metal oxides. Preferred are tetracyanoquinodimethane (TCNQ), tetrafluorotetracyanoquinodimethane (F₄-TCNQ) and molybdenum oxide.

The electron accepting dopant in the hole injection layer is preferably contained in an amount of 0.01% by mass to 50% by mass, more preferably 0.1% by mass to 40% by mass, even more preferably 0.5% by mass to 30% by mass, with respect to the total mass of the compound constituting the hole injection layer.

—Electron Injection Layer, Electron Transporting Layer—

The electron injection layer and the electron transporting layer are layers that have the ability of transporting electrons from the cathode or the side of the cathode to the anode side.

The electron injection layer preferably contains an electron donating dopant. When the electron donating dopant is contained in the electron injection layer, there are effects such as improvement of electron injection property, deterioration in driving voltage and improvement in efficiency.

Any organic or inorganic material may be used as the electron donating dopant so long as it can supply electrons to a doped material and produce radical anions. Examples of the electron donating dopant include tetrathiafulvalene (TTF), tetrathianaphthacene (TTT), lithium, cesium and the like.

Regarding the hole injection layer, the hole transporting layer, the electron injection layer and the electron transporting layer, the contents described in the paragraphs [0165] to of JP-A-2008-270736 may be applied to the present invention.

In the device of the present invention, the device containing an electron accepting dopant or an electron donating dopant exhibits improved external quantum efficiency than a device not containing them. The reason for this is not clear, but it is thought as follows. When an electron injection property or hole injection property is improved, the balance of electric charge in the light emitting layer is broken and light emission position varies. When the hole injection property is improved, electric charges are accumulated on the interface of the side of the cathode of the light emitting layer and a light emission ratio increases at the position, and when the electron injection property is improved, electric charges are accumulated on the interface of the side of the anode of the light emitting layer and a light emission ratio increases at the position. In devices containing no electron accepting dopant or electron donating dopant exhibits great variation of this light emission position, efficiency is greatly deteriorated due to inactivation of excitons caused by the hole block layer and the electron block layer, while devices containing an electron accepting dopant or an electron donating dopant do not exhibit great variation in light emission position and maintain efficiencies. As a result, it is thought that the relative value of external quantum efficiency.

The electron donating dopant is contained in an amount of preferably 0.01% by mass to 50% by mass, more preferably 0.1% by mass to 40% by mass, even more preferably 0.5% by mass to 30% by mass, in the electron injection layer, with respect to the total mass of compounds constituting the electron injection layer.

—Hole Block Layer—

The hole block layer is a layer which prevents holes transported from the side of the anode to the light emitting layer from being escaped into the cathode. In the present invention, a hole block layer may be mounted as an organic layer adjacent to the light emitting layer in the side of the cathode.

Examples of the organic compound constituting the hole block layer include aluminum complexes such as aluminum (III) bis(2-methyl-8-quinolinato)4-phenylphenolate (simply referred to “BAlq”)), triazole derivatives, phenanthroline derivatives such as 2,9-dimethyl-4,7-diphenyl-1,10-phenanthroline (simply referred to “BCP”)), and the like.

The thickness of the hole block layer is preferably 1 nm to 500 nm, more preferably 5 nm to 200 nm, even more preferably 10 nm to 100 nm.

The hole block layer may be a monolayer made of one or more of the aforementioned materials, or a multilayer structure including a plurality of layers which have identical or different compositions.

—Electron Block Layer—

The electron block layer is a layer which prevents electrons transported from the cathode side to the light emitting layer from being escaped into the side of the anode. In the present invention, the electron block layer may be mounted as an organic layer adjacent to the light emitting layer in the side of the anode.

Examples of the organic compound constituting the electron block layer include those of the aforementioned examples of the hole transporting material.

The thickness of the electron block layer is preferably 1 nm to 500 nm, more preferably 5 nm to 200 nm, even more preferably 10 nm to 100 nm.

The electron block layer may be a monolayer made of one or more of the aforementioned materials, or a multilayer structure including two or more layers which have identical or different compositions.

<Protective Layer>

In the present invention, the organic EL device may be protected with a protective layer.

Regarding the protective layer, the content described in the paragraphs of [0169] to of JP-A-2008-270736 may be applied to the present invention.

<Sealing Container>

The device of the present invention may be sealed using a sealing container.

Regarding the sealing container, the content described in the paragraph of [0171] of JP-A-2008-270736 may be applied to the present invention.

(Driving)

The organic electroluminescence device of the present invention emits light by applying a direct voltage (may further include an alternating component, if necessary) between an anode and a cathode (commonly, 2 volt to 15 volt), or direct current.

The driving method of the organic electroluminescence device of the present invention may use driving methods described in the specifications of JP-A-2-148687, JP-A-6-301355, JP-A-5-29080, JP-A-7-134558, JP-A-8-234685, JP-A-8-241047, Japanese Patent No. 2784615, U.S. Pat. No. 5,828,429, and U.S. Pat. No. 6,023,308.

The luminescence device of the present invention can improve light extraction efficiency through various known methods. For example, light extraction efficiency and external quantum efficiency can be improved by processing the shape of substrate surface (for example, formation of fine roughness patterns), controlling refraction of substrate•ITO layer•organic layer, and controlling the thickness of substrate•ITO layer•organic layer.

The external quantum efficiency of the luminescence device of the present invention is preferably 15% to 30%. As the value of external quantum efficiency, a maximum external quantum efficiency when a device is driven at 80° C., or an external quantum efficiency of about 100 to 1000 cd/m² when a device is driven at 80° C. may be used.

The luminescence device of the present invention may be so-called a “top-emission type” in which light is emitted from the side of the anode.

The organic EL device of the present invention may have a resonator structure. For example, the organic EL device has a multi-layer film mirror including a plurality of laminated films having different refractive indexes, a transparent or semitransparent electrode, a light emitting layer and a metal electrode disposed on a transparent substrate. The light emitted from the light emitting layer is resonated by repeatedly being reflected between the multi-layer film mirror and a metal electrode as a reflection plate.

In more preferred embodiments, a transparent or semitransparent electrode and a metal electrode are served as reflection plates on a transparent substrate and light emitted from the light emitting layer is resonated by repeatedly being reflected therebetween.

To form the resonance structure, light passage length determined by effective refractive index of two reflection plates, refractive indexes of respective layers between the reflection plates and the thickness is adjusted to the most preferred value. In the first embodiment, the calculation equation is described in the specification of JP-A-9-180883. In the second embodiment, the calculation equation is described in the specification of JP-A-2004-127795.

(Use of the Luminescence Device of the Present Invention)

The luminescence device of the present invention may be preferably used for light emission apparatuses, pexels, display devices, displays, backlights, electrophotography, illumination light sources, recording light sources, exposure light sources, reading light sources, covers, signboards, interiors, optical communications and the like. In particular, the luminescence device is preferably used for devices which are driven in regions with high light emitting luminance intensity such as illumination apparatuses and display apparatuses.

(Light Emission Apparatus)

Then, the light emission apparatus of the present invention will be described with reference to FIG. 2.

The light emission apparatus of the present invention uses an organic electroluminescence device.

FIG. 2 is a sectional view schematically illustrating an example of a light emission apparatus of the present invention.

The light emission apparatus 20 of FIG. 2 includes a substrate (support substrate) 2, an organic electroluminescence device 10 and a sealing container 16.

The organic electroluminescence device 10 includes an anode (first electrode) 3, an organic layer 11, and a cathode (second electrode) 9 laminated on a substrate 2. In addition, the protective layer 12 is laminated on the cathode 9, and a sealing container 16 is mounted via an adhesive layer 14 on the protective layer 12. Furthermore, the part, barrier and insulating layer of respective electrodes 3 and 9 are omitted.

Here, a photosetting adhesive such as an epoxy resin or a thermosetting adhesive may be used as the adhesive layer 14 and, for example, a thermosetting adhesive sheet may be also used.

The use of the light emission apparatus of the present invention is not particularly limited and example thereof include illumination apparatuses as well as display apparatuses such as TVs, personal computers, cellular phones and electron papers.

(Illumination Apparatus)

Then, an illumination apparatus according to an embodiment of the present invention will be described with reference to FIG. 3.

FIG. 3 is a sectional view schematically illustrating an example of an illumination apparatus according to one embodiment of the present invention.

As shown in FIG. 3, the illumination apparatus 40 according to the embodiment of the present invention includes the aforementioned organic EL device 10 and a light scattering member 30. More specifically, the illumination apparatus 40 has a structure in which the substrate of the organic EL device 10 contacts the light scattering member 30.

Any material may be used as the light scattering member 30 so long as it can scatter light. As shown in FIG. 3, particles 32 are dispersed on a transparent substrate 31. Preferably, the transparent substrate 31 is for example a glass substrate. The particle 32 is preferably a transparent resin particle. The glass substrate and the transparent resin particle may be selected from known materials. Such an illumination apparatus 40 scatters the incident light through the light scattering member 30 and emits the scattered light from a light emission surface 30B as an illumination light, when light emitted from an organic electroluminescence device 10 is incident on a light incident surface 30A of the light scattering member 30.

### EXAMPLES

Hereinafter, the present invention will be described in detail with reference to examples in more detail and is not limited to the following specific examples.

The compound represented by Formula (1) or (2) used in Example is synthesized in accordance with WO 2004/074399 or the like. For example, the compound (A-1) is synthesized in accordance with the method described in WO 2004/074399, page 52, line 22 to page 54, line 15. The compound represented by Formula (PI-1) was synthesized in accordance with US Patent Application Publication Nos. 2007/0190359 and 2008/0297033. For example, the compound 1 was synthesized in accordance with a method described in US Patent Application Publication Nos. 2007/0190359, page 44, [0104] to page 45, [0107].

Furthermore, all organic materials used in this example were sublimation-purified and analyzed by high-performance liquid chromatography (Tosoh TSKgel ODS-100Z), and materials having 99.9% or higher of an absorption intensity area ratio at 254 nm were used.

### Example 1-1

A glass substrate (produced by GEOMATEC CO., LTD, surface resistance: 10Ω/□) having an indium tin oxide (ITO) film with a thickness of 0.5 mm and 2.5 cm square was incorporated into a cleaning container, ultrasonic cleaned in 2-propanol and treated with UV-ozone for 30 minutes. The following organic layers were sequentially deposited on the transparent anode (ITO film) by a vacuum deposition method.

First layer: CuPc (copper phthalocyanine): thickness 10 nm

Second layer: NPD (N,N′-di-α-naphthyl-N,N′-diphenyl)-benzidine): thickness 30 nm

Third layer: CBP (4,4′-di(9-carbazolyl)biphenyl): thickness 5 nm

Fourth layer: Compound 1 (5% by mass), A-1 (95% by mass): thickness 30 nm

Fifth layer: BAlq: thickness 30 nm

Lithium fluoride was deposited to a thickness of 0.2 nm thereon and metal aluminum was then deposited to a thickness of 70 nm thereon to obtain a cathode.

The obtained laminate was incorporated into a grove box replaced with an argon gas without contacting an air, sealed using a sealing can made of stainless steel and a UV curable adhesive (XNR5516HV, produced by Nagase Chiba Co., Ltd.) to obtain an organic electroluminescence device of Example 1-1.

### Examples 1-2 to 1-31 and Comparative Examples 1-1 to 1-9

Organic electroluminescence devices of Examples 1-2 to 1-31 and Comparative Examples 1-1 to 1-9 were obtained in the same manner as in Example 1-1 except that the material constituting the fourth layer in Example 1-1 was changed into the material shown in the following Table 1. In Table 1, for evaluation of variation in chromaticity, the symbol “<” means a sign of inequality, and, for example, “<0.005” means that variation in chromaticity is lower than 0.005.

TABLE 1

| | | | External | | | |
|---|---|---|---|---|---|---|
| | | | quantum | | | |
| | | | efficiency | Durability | Variation | Variation in |
| | | | (relative | (relative | in voltage | chromaticity |
| | Host | Dopant | value) | value) | ΔV | (Δx, Δy) |
| Ex. 1-1 | A-1 | Compound 1 | 140 | 680 | 0.81 | (<0.005, <0.005) |
| Ex. 1-2 | A-1 | Compound 2 | 152 | 500 | 0.85 | (<0.005, <0.005) |
| Ex. 1-3 | A-1 | Compound 5 | 135 | 650 | 0.83 | (<0.005, <0.005) |
| Ex. 1-4 | A-1 | Compound 8 | 143 | 520 | 0.91 | (<0.005, <0.005) |
| Ex. 1-5 | A-1 | Compound 10 | 145 | 360 | 1.05 | (<0.005, <0.005) |
| Ex. 1-6 | A-1 | Compound 16 | 151 | 820 | 0.75 | (<0.005, <0.005) |
| Ex. 1-7 | A-1 | Compound 21 | 138 | 440 | 0.85 | (<0.005, <0.005) |
| Ex. 1-8 | A-1 | Compound 28 | 142 | 280 | 1.06 | (<0.005, <0.005) |
| Ex. 1-9 | A-4 | Compound 1 | 125 | 600 | 0.78 | (<0.005, <0.005) |
| Ex. 1-10 | A-4 | Compound 2 | 142 | 420 | 0.78 | (<0.005, <0.005) |
| Ex. 1-11 | A-4 | Compound 8 | 145 | 550 | 0.83 | (<0.005, <0.005) |
| Ex. 1-12 | A-4 | Compound 16 | 133 | 740 | 0.72 | (<0.005, <0.005) |
| Ex. 1-13 | A-9 | Compound 1 | 140 | 450 | 0.85 | (<0.005, <0.005) |
| Ex. 1-14 | A-9 | Compound 2 | 145 | 300 | 0.85 | (<0.005, <0.005) |
| Ex. 1-15 | A-9 | Compound 16 | 140 | 500 | 0.80 | (<0.005, <0.005) |
| Ex. 1-16 | A-12 | Compound 1 | 144 | 400 | 0.90 | (<0.005, <0.005) |
| Ex. 1-17 | A-12 | Compound 2 | 130 | 320 | 0.85 | (<0.005, <0.005) |
| Ex. 1-18 | A-12 | Compound 16 | 136 | 480 | 0.88 | (<0.005, <0.005) |
| Ex. 1-19 | A-12 | Compound 21 | 144 | 440 | 0.95 | (<0.005, <0.005) |
| Ex. 1-20 | A-14 | Compound 1 | 152 | 320 | 1.02 | (<0.005, <0.005) |
| Ex. 1-21 | A-14 | Compound 16 | 150 | 380 | 0.95 | (<0.005, <0.005) |
| Ex. 1-22 | A-19 | Compound 1 | 142 | 550 | 0.77 | (<0.005, <0.005) |
| Ex. 1-23 | A-19 | Compound 8 | 148 | 480 | 0.92 | (<0.005, <0.005) |
| Ex. 1-24 | A-19 | Compound 16 | 155 | 660 | 0.81 | (<0.005, <0.005) |
| Ex. 1-25 | A-22 | Compound 1 | 135 | 380 | 0.98 | (<0.005, <0.005) |
| Ex. 1-26 | A-22 | Compound 2 | 141 | 350 | 0.92 | (<0.005, <0.005) |
| Ex. 1-27 | A-22 | Compound 16 | 138 | 400 | 0.81 | (<0.005, <0.005) |
| Ex. 1-28 | A-1 | Compound 22 | 126 | 250 | 1.12 | (<0.005, <0.005) |
| Ex. 1-29 | A-1 | Compound 24 | 128 | 270 | 1.14 | (<0.005, <0.005) |
| Ex. 1-30 | A-1 | Compound 43 | 125 | 290 | 1.13 | (<0.005, <0.005) |
| Ex. 1-31 | A-1 | Compound 46 | 124 | 290 | 1.10 | (<0.005, <0.005) |
| Comp. Ex. 1-1 | H-1 | Firpic | 100 | 100 | 2.21 | (0.01, 0.03) |
| Comp. Ex. 1-2 | H-1 | Compound 1 | 90 | 130 | 1.85 | (0.01, 0.02) |
| Comp. Ex. 1-3 | H-1 | Compound 16 | 95 | 150 | 1.78 | (0.01, 0.02) |
| Comp. Ex. 1-4 | H-2 | Firpic | 85 | 120 | 2.35 | (0.02, 0.03) |
| Comp. Ex. 1-5 | H-2 | Compound 1 | 118 | 170 | 1.80 | (0.01, 0.02) |
| Comp. Ex. 1-6 | H-2 | Compound 21 | 110 | 140 | 1.86 | (0.01, 0.02) |
| Comp. Ex. 1-7 | A-1 | Firpic | 115 | 120 | 2.02 | (<0.005, 0.02) |
| Comp. Ex. 1-8 | A-4 | Firpic | 112 | 140 | 1.96 | (0.01, 0.02) |
| Comp. Ex. 1-9 | A-14 | Firpic | 105 | 90 | 2.10 | (0.01, 0.03) |

### Example 2-1

A glass substrate (produced by GEOMATEC CO., LTD, surface resistance: 10Ω/□) having an indium tin oxide (ITO) film with a thickness of 0.5 mm and 2.5 cm square was incorporated into a cleaning container, ultrasonic cleaned in 2-propanol and treated with UV-ozone for 30 minutes. The following organic layers were sequentially deposited on the transparent anode (ITO film) by a vacuum deposition method.

First layer: CuPc (copper phthalocyanine): thickness 10 nm

Second layer: NPD (N,N′-di-α-naphthyl-N,N′-diphenyl)-benzidine): thickness 30 nm

Third layer: Compound 1 (5% by mass), A-1 (95% by mass): thickness 30 nm

Fourth layer: A-1: thickness 5 nm

Fifth layer: Alq (tris(8-hydroxyquinoline)aluminum complex): thickness 40 nm

Lithium fluoride was deposited to a thickness of 0.2 nm thereon and metal aluminum was then deposited to a thickness of 70 nm thereon to obtain a cathode.

The obtained laminate was incorporated into a grove box replaced with an argon gas without contacting an air, sealed using a sealing can made of stainless steel and a UV curable adhesive (XNR5516HV, produced by Nagase Chiba Co., Ltd.) to obtain an organic electroluminescence device of Example 2-1.

### Examples 2-2 to 2-5 and Comparative Examples 2-1 to 2-3

Organic electroluminescence devices of Examples 2-2 to 2-5 and Comparative Examples 2-1 to 2-3 were obtained in the same manner as in Example 2-1 except that the compound 1 used for the third layer and A-1 used for the third and fourth layers in Example 2-1 were changed into materials shown in the following Table 2. In Table 2, for evaluation of variation in chromaticity, the symbol “<” means a sign of inequality, and, for example, “<0.005” means that variation in chromaticity is lower than 0.005.

TABLE 2

| | | Third | External | | | |
|---|---|---|---|---|---|---|
| | | layer | quantum | | Variation | |
| | | and | efficiency | Durability | in | Variation in |
| | | fourth | (relative | (relative | voltage | chromaticity |
| | Third layer | layer | value) | value) | ΔV | (Δx, Δy) |
| Ex. 2-1 | Compound 1 | A-1 | 155 | 680 | 0.69 | (<0.005, <0.005) |
| Ex. 2-2 | Compound 1 | A-4 | 133 | 580 | 0.78 | (<0.005, <0.005) |
| Ex. 2-3 | Compound 1 | A-10 | 142 | 650 | 0.75 | (<0.005, <0.005) |
| Ex. 2-4 | Compound 16 | A-4 | 140 | 590 | 0.85 | (<0.005, <0.005) |
| Ex. 2-5 | Compound 16 | A-22 | 138 | 450 | 0.81 | (<0.005, <0.005) |
| Comp. Ex. 2-1 | Firpic | H-1 | 100 | 100 | 1.88 | (0.02, 0.03) |
| Comp. Ex. 2-2 | Firpic | A-1 | 125 | 180 | 1.25 | (<0.005, 0.02) |
| Comp. Ex. 2-3 | Compound 1 | H-2 | 120 | 180 | 1.74 | (0.01, 0.01) |

### Example 3-1

A glass substrate (produced by GEOMATEC CO., LTD, surface resistance: 10Ω/□) having an indium tin oxide (ITO) film with a thickness of 0.5 mm and 2.5 cm square was incorporated into a cleaning container, ultrasonic cleaned in 2-propanol and treated with UV-ozone for 30 minutes. The following organic layers were sequentially deposited on the transparent anode (ITO film) by a vacuum deposition method.

First layer: CuPc (copper phthalocyanine): thickness 10 nm

Second layer: NPD (N,N′-di-α-naphthyl-N,N′-diphenyl)-benzidine): thickness 30 nm

Third layer: A-1: thickness 5 nm

Fourth layer: Compound 1 (5% by mass), A-1 (95% by mass): thickness 30 nm

Fifth layer: BAlq: thickness 30 nm

Lithium fluoride was deposited to a thickness of 0.2 nm thereon and metal aluminum was then deposited to a thickness of 70 nm thereon to obtain a cathode.

The obtained laminate was incorporated into a grove box replaced with an argon gas without contacting an air, sealed using a sealing can made of stainless steel and a UV curable adhesive (XNR5516HV, produced by Nagase Chiba Co., Ltd.) to obtain an organic electroluminescence device of Example 3-1.

### Examples 3-2 to 3-6 and Comparative Examples 3-1 to 3-3

Organic electroluminescence devices of Examples 3-2 to 3-6 and Comparative Examples 3-1 to 3-3 were obtained in the same manner as in Example 3-1 except that A-1 used for the third and fourth layers and Compound 1 used for the fourth layer in Example 3-1 were changed into the material shown in the following Table 3. In Table 3, for evaluation of variation in chromaticity, the symbol “<” means a sign of inequality, and, for example, “<0.005” means that variation in chromaticity is lower than 0.005.

TABLE 3

| | Third | | External | | | |
|---|---|---|---|---|---|---|
| | layer | | quantum | | Variation | |
| | and | | efficiency | Durability | in | Variation in |
| | fourth | | (relative | (relative | voltage | chromaticity |
| | layer | Fourth layer | value) | value) | ΔV | (Δx, Δy) |
| Ex. 3-1 | A-1 | Compound 1 | 250 | 520 | 0.91 | (<0.005, <0.005) |
| Ex. 3-2 | A-1 | Compound 16 | 232 | 610 | 0.88 | (<0.005, <0.005) |
| Ex. 3-3 | A-1 | Compound 28 | 245 | 310 | 1.01 | (<0.005, <0.005) |
| Ex. 3-4 | A-4 | Compound 8 | 253 | 400 | 0.98 | (<0.005, <0.005) |
| Ex. 3-5 | A-9 | Compound 21 | 225 | 490 | 1.08 | (<0.005, <0.005) |
| Ex. 3-6 | A-19 | Compound 20 | 270 | 460 | 0.85 | (<0.005, <0.005) |
| Comp. Ex. 3-1 | H-1 | Firpic | 100 | 100 | 2.85 | (0.02, 0.04) |
| Comp. Ex. 3-2 | A-1 | Firpic | 185 | 180 | 1.88 | (0.01, 0.02) |
| Comp. Ex. 3-3 | H-2 | Compound 16 | 110 | 130 | 2.55 | (0.01, 0.02) |

### Example 4-1

A glass substrate (produced by GEOMATEC CO., LTD, surface resistance: 10Ω/□) having an indium tin oxide (ITO) film with a thickness of 0.5 mm and 2.5 cm square was incorporated into a cleaning container, ultrasonic cleaned in 2-propanol and treated with UV-ozone for 30 minutes. A PEDOT (poly(3,4-ethylenedioxythiophene))/PSS (polystyrenesulfonic acid) aqueous solution (BaytronP (standard product)) was spin-coated (4000 rpm, 60 seconds) thereon and dried at 120° C. for 10 minutes to form a hole transporting layer (thickness 150 nm).

A toluene solution containing 1% by mass of a compound A-1 and 0.05% by mass of a compound 1 was spin-coated (2000 rpm, 60 seconds) thereon to form a light emitting layer (thickness 50 nm). BAlq [bis-(2-methyl-8-quinolinate)-4-(phenylphenolate)aluminum] was deposited to 40 nm by a vacuum deposition method to obtain an electron transporting layer, lithium fluoride and metal aluminum were sequentially deposited to 0.2 nm and 150 nm, respectively, to obtain a cathode. The obtained structure was incorporated into a grove box replaced with an argon gas without contacting an air, sealed using a sealing can made of stainless steel and a UV curable adhesive (XNR5516HV, produced by Nagase Chiba Co., Ltd.) to obtain an organic electroluminescence device of Example 4-1.

### Examples 4-2 to 4-4 and Comparative Examples 4-1 to 4-3

Organic electroluminescence devices of Examples 4-2 to 4-4 and Comparative Examples 4-1 to 4-3 were obtained in the same manner as in Example 4-1 except that the material constituting the light emitting layer in Example 4-1 was changed into the material shown in the following Table 4. In Table 4, for evaluation of variation in chromaticity, the symbol “<” means a sign of inequality, and, for example, “<0.005” means that variation in chromaticity is lower than 0.005.

TABLE 4

| | | | External | | | |
|---|---|---|---|---|---|---|
| | | | quantum | | Variation | |
| | | | efficiency | Durability | in | Variation in |
| | | | (relative | (relative | voltage | chromaticity |
| | Host | Dopant | value) | value) | ΔV | (Δx, Δy) |
| Ex. 4-1 | A-1 | Compound 1 | 172 | 480 | 1.07 | (<0.005, <0.005) |
| Ex. 4-2 | A-4 | Compound 2 | 154 | 520 | 1.21 | (<0.005, <0.005) |
| Ex. 4-3 | A-9 | Compound 21 | 140 | 550 | 1.08 | (<0.005, 0.01) |
| Ex. 4-4 | A-14 | Compound 8 | 138 | 320 | 1.37 | (<0.005, 0.01) |
| Comp. Ex. 4-1 | H-1 | Firpic | 100 | 100 | 3.05 | (0.02, 0.03) |
| Comp. Ex. 4-2 | A-1 | Firpic | 85 | 150 | 2.76 | (0.02, 0.03) |
| Comp. Ex. 4-3 | H-2 | Compound 1 | 124 | 130 | 2.38 | (0.01, 0.03) |

### Example 5-1

A glass substrate (produced by GEOMATEC CO., LTD, surface resistance: 10Ω/□) having an indium tin oxide (ITO) film with a thickness of 0.5 mm and 2.5 cm square was incorporated into a cleaning container, ultrasonic cleaned in 2-propanol and treated with UV-ozone for 30 minutes. The following organic layers were sequentially deposited on the transparent anode (ITO film) by a vacuum deposition method.

First layer: CuPc (copper phthalocyanine): thickness 10 nm

Second layer: NPD (N,N′-di-α-naphthyl-N,N′-diphenyl)-benzidine): thickness 20 nm

Third layer: CBP (4,4′-di(9-carbazolyl)biphenyl): thickness 5 nm

Fourth layer: compound 1 (5% by mass), A-1 (95% by mass): thickness 30 nm

Fifth layer: BAlq: thickness 10 nm

Fifth layer: BCP (99% by mass), Li (1% by mass): thickness 30 nm

Lithium fluoride was deposited to a thickness of 0.2 nm thereon and metal aluminum was then deposited to a thickness of 70 nm thereon to obtain a cathode.

The obtained laminate was incorporated into a grove box replaced with an argon gas without contacting an air, sealed using a sealing can made of stainless steel and a UV curable adhesive (XNR5516HV, produced by Nagase Chiba Co., Ltd.) to obtain an organic electroluminescence device of Example 5-1.

### Examples 5-2 to 5-4 and Comparative Examples 5-1 to 5-4

Organic electroluminescence devices of Examples 5-2 to 5-4 and Comparative Examples 5-1 to 5-4 were obtained in the same manner as in Example 5-1 except that the compound 1 and A-1 used for the fourth layer in Example 5-1 were changed into materials shown in the following Table 5. In Table 5, for evaluation of variation in chromaticity, the symbol “<” means a sign of inequality, and, for example, “<0.005” means that variation in chromaticity is lower than 0.005.

TABLE 5

| | | | External | | | |
|---|---|---|---|---|---|---|
| | | | quantum | Durability | Variation | Variation in |
| | | | efficiency | (relative | in voltage | chromaticity |
| | Host | Dopant | (relative value) | value) | ΔV | (Δx, Δy) |
| Ex. 5-1 | A-1 | Compound 1 | 168 | 530 | 0.93 | (<0.005, <0.005) |
| Ex. 5-2 | A-4 | Compound 2 | 157 | 560 | 0.96 | (<0.005, <0.005) |
| Ex. 5-3 | A-9 | Compound 16 | 163 | 480 | 1.01 | (<0.005, <0.005) |
| Ex. 5-4 | A-19 | Compound 5 | 152 | 400 | 1.05 | (<0.005, <0.005) |
| Comp. Ex. 5-1 | H-1 | Firpic | 100 | 100 | 2.02 | (0.02, 0.04) |
| Comp. Ex. 5-2 | H-2 | Firpic | 75 | 50 | 2.14 | (0.01, 0.04) |
| Comp. Ex. 5-3 | A-1 | Firpic | 105 | 150 | 1.99 | (0.01, 0.03) |
| Comp. Ex. 5-4 | H-1 | Compound 1 | 112 | 130 | 2.03 | (0.01, 0.02) |

### Example 6-1

A glass substrate (produced by GEOMATEC CO., LTD, surface resistance: 10Ω/□) having an indium tin oxide (ITO) film with a thickness of 0.5 mm and 2.5 cm square was incorporated into a cleaning container, ultrasonic cleaned in 2-propanol and treated with UV-ozone for 30 minutes. The following organic layers were sequentially deposited on the transparent anode (ITO film) by a vacuum deposition method.

First layer: 2-TNATA (99.7% by mass), F₄-TCNQ (0.3% by mass): thickness 50 nm

Second layer: NPD (N,N′-di-α-naphthyl-N,N′-diphenyl)-benzidine): thickness 10 nm

Third layer: CBP (4,4′-di(9-carbazolyl)biphenyl): thickness 5 nm

Fourth layer: Compound 1 (5% by mass), A-1 (95% by mass): thickness 30 nm

Fifth layer: BAlq: thickness 10 nm

Lithium fluoride was deposited to a thickness of 0.2 nm thereon and metal aluminum was then deposited to a thickness of 70 nm thereon to obtain a cathode.

The obtained laminate was incorporated into a grove box replaced with an argon gas without contacting an air, sealed using a sealing can made of stainless steel and a UV curable adhesive (XNR5516HV, produced by Nagase Chiba Co., Ltd.) to obtain an organic electroluminescence device of Example 6-1.

### Examples 6-2 to 6-4 and Comparative Examples 6-1 to 6-4

Organic electroluminescence devices of Examples 6-2 to 6-4 and Comparative Examples 6-1 to 6-4 were obtained in the same manner as in Example 6-1 except that the compound 1 and A-1 used for the fourth layer in Example 6-1 were changed into materials shown in the following Table 6. In Table 6, for evaluation of variation in chromaticity, the symbol “<” means a sign of inequality, and, for example, “<0.005” means that variation in chromaticity is lower than 0.005.

TABLE 6

| | | | External | | | |
|---|---|---|---|---|---|---|
| | | | quantum | | Variation | |
| | | | efficiency | Durability | in | Variation in |
| | | | (relative | (relative | voltage | chromaticity |
| | Host | Dopant | value) | value) | ΔV | (Δx, Δy) |
| Ex. 6-1 | A-1 | Compound 1 | 155 | 510 | 0.95 | (<0.005, <0.005) |
| Ex. 6-2 | A-4 | Compound 2 | 148 | 400 | 1.01 | (<0.005, <0.005) |
| Ex. 6-3 | A-9 | Compound 5 | 154 | 380 | 1.07 | (<0.005, <0.005) |
| Ex. 6-4 | A-19 | Compound 16 | 163 | 550 | 0.98 | (<0.005, <0.005) |
| Comp. Ex. 6-1 | H-1 | Firpic | 100 | 100 | 2.17 | (0.01, 0.03) |
| Comp. Ex. 6-2 | H-2 | Firpic | 90 | 40 | 2.21 | (0.01, 0.03) |
| Comp. Ex. 6-3 | A-1 | Firpic | 96 | 130 | 1.95 | (0.01, 0.03) |
| Comp. Ex. 6-4 | H-1 | Compound 1 | 108 | 140 | 1.89 | (<0.005, 0.03) |

(Evaluation of Performance of Organic Electroluminescence Device)

The performance of respective devices thus obtained was evaluated as follows.

(a) External Quantum Efficiency During Driving at High Temperature

DC voltage was applied to respective devices at 80° C. in a thermostat using Source Measure Unit 2400 produced by Toyo Corporation to emit light, and the luminance intensity was measured using BM-8 produced by Topcon Corporation as a luminance intensity meter. Luminescent spectra and luminescent wavelengths were measured using a spectrum analyzer, PMA-11 produced by Hamamatsu Photonics K.K. Based on these values, external quantum efficiency at a luminance intensity of 360 cd/m² was calculated by a luminance intensity conversion method, the value of Comparative Example 1-1 in Table 1, the value of Comparative Example 2-1 in Table 2, the value of Comparative Example 3-1 in Table 3, the value of Comparative Example 4-1 in Table 4, the value of Comparative Example 5-1 in Table 5 and the value of Comparative Example 6-1 in Table 6 were set at 100 respectively and external quantum efficiencies were expressed as relative values with respect to these values in respective tables. The external quantum efficiency is preferably superior, as the value thereof increases.

(b) Durability During Driving at High Temperature

Respective devices were subjected to emitting light at 80° C. in a thermostat by applying a DC voltage thereto such that luminance intensity became 1000 cd/m², the time taken until luminance intensity became 500 cd/m² was set as an indicator of driving durability, the value of Comparative Example 1-1 in Table 1, the value of Comparative Example 2-1 in Table 2, the value of Comparative Example 3-1 in Table 3, the value of Comparative Example 4-1 in Table 4, the value of Comparative Example 5-1 in Table 5 and the value of Comparative Example 6-1 in Table 6 were set to 100 respectively and durabilities were expressed as relative values with respect to these values in respective tables. The external quantum efficiency is preferably superior as the value thereof increases.

(c) Variation in Voltage after Driving at High Temperature

A difference between a DC voltage applied to each device in a 80° C. thermostat such that luminance intensity became 1000 cd/m² and a voltage applied thereto when luminance intensity became 500 cd/m² after a DC voltage was continuously applied thereto, was set as an indicator of variation in voltage after driving at a high temperature and the value was expressed as a variation in voltage ΔV(V). The variation in voltage ΔV is preferably superior, as the value thereof decreases.

(d) Variation in Chromaticity after High-Temperature Driving

Differences (Δx, Δy) in values x and y between chromaticity applied to each device in a 80° C. thermostat such that luminance intensity became 1000 cd/m², and chromaticity applied thereto when luminance intensity became 500 cd/m² after a DC voltage was continuously applied thereto, was set as an indicator of variation in chromaticity after driving at a high temperature and the value was expressed as (Δx, Δy). The variation in chromaticity is preferably superior, as the value thereof decreases.

As can be seen from the results of Tables 1 to 6, the device of the present invention using a host material containing a carbazole group represented by Formula (1) or (2) and a specific iridium complex represented by Formula (PI-1) exhibited superior properties in terms of external quantum efficiency and durability during driving at high temperatures, and variation in voltage and variation in chromaticity after driving at high temperatures, as compared to the device of Comparative Example, and, in particular, exhibited considerably superior durability during driving at a high temperature.

The reason that the light emitting material and the host material of the present invention improve device performance after driving at high temperatures and, in particular, durability is not clear, but is thought as follows. As compared to room temperature, a device was driven at a high temperature, the film state may be readily changed and device defects readily occur. This behavior is thought to be observed in a material with a low molecular weight having a low glass transition temperature, materials that are readily crystallized due to large symmetricity and intermolecular interaction. In addition, in iridium complex-based phosphorescent materials, production of decomposer and quencher caused by isolation of the ligand which is a fate of the complex material is considered to deteriorate device performance. This deposition reaction also worsens with driving at high temperatures. In the present invention, variation in film state can be decreased by using a host material that has a large molecular weight and does not readily cause crystallization, and the stability of iridium complex can be improved by making the ligand of the light emitting material as condensed rings so as to be able to suppressing the isolation of the ligand. As a result, device performance is thought to be considerably improved due to these reasons.

Light emission apparatuses, display apparatuses and illumination apparatuses necessarily momentarily emit light with high luminance intensity based on high current density in respective pixels. In this case, the luminescence device of the present invention is advantageously used since it is designed such that it exhibits a high light emitting efficiency.

In addition, the device of the present invention exhibits superior light emitting efficiency or durability although used under high temperature conditions such as vehicle-mounting application and is thus preferably used for light emission apparatuses, display apparatuses and illumination apparatuses.

The structures of compounds used in Examples and Comparative Examples are shown as follows.

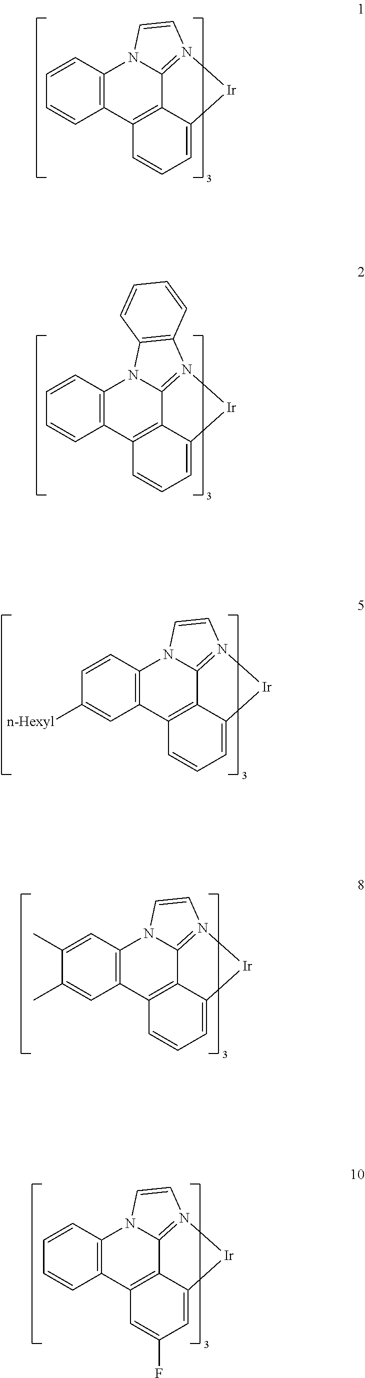

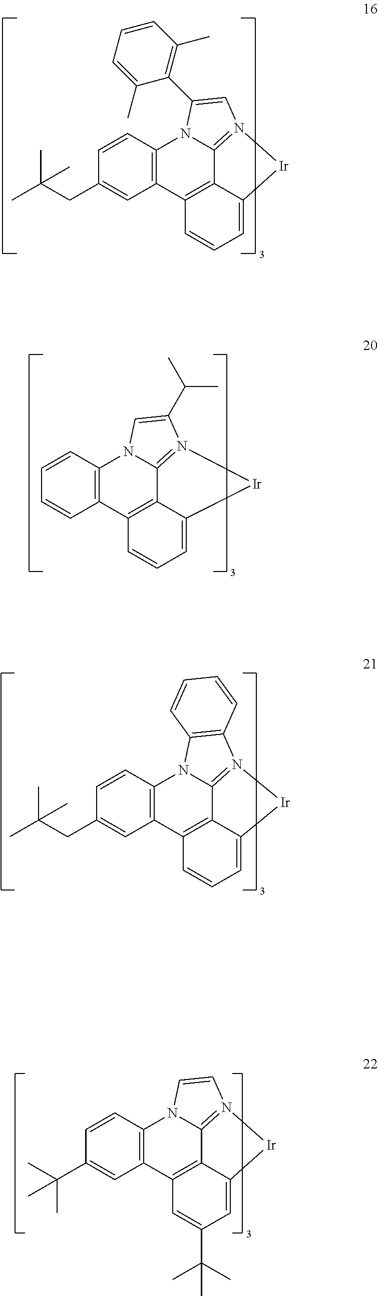

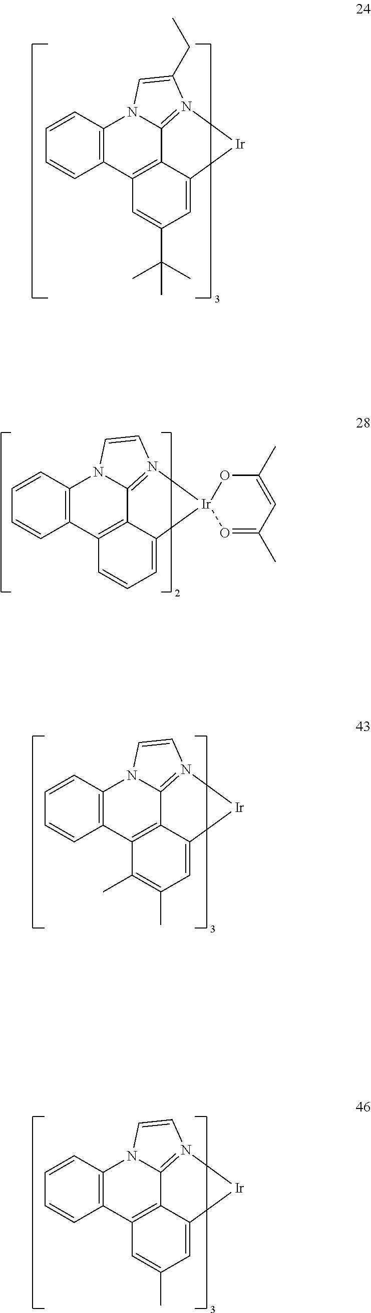

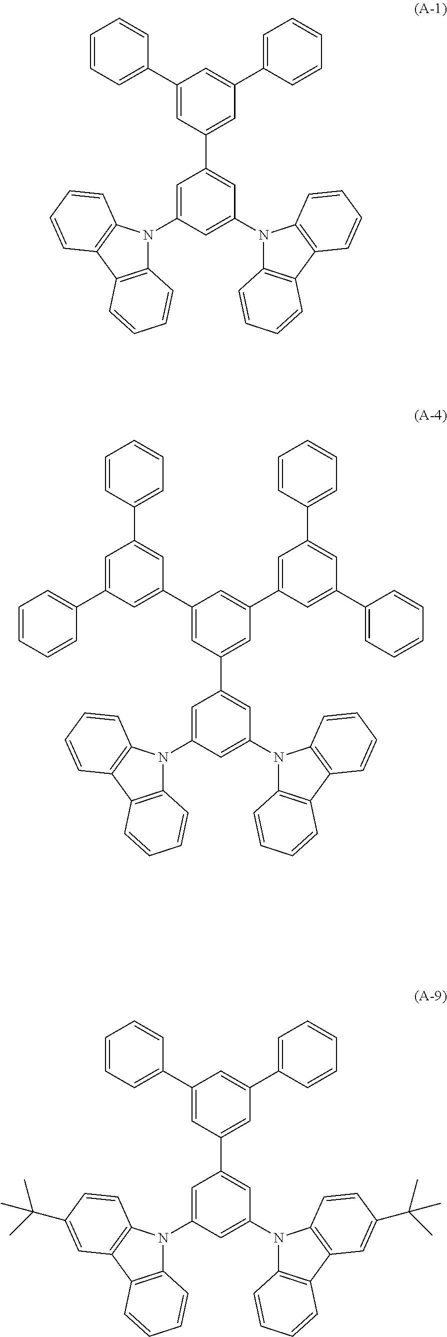

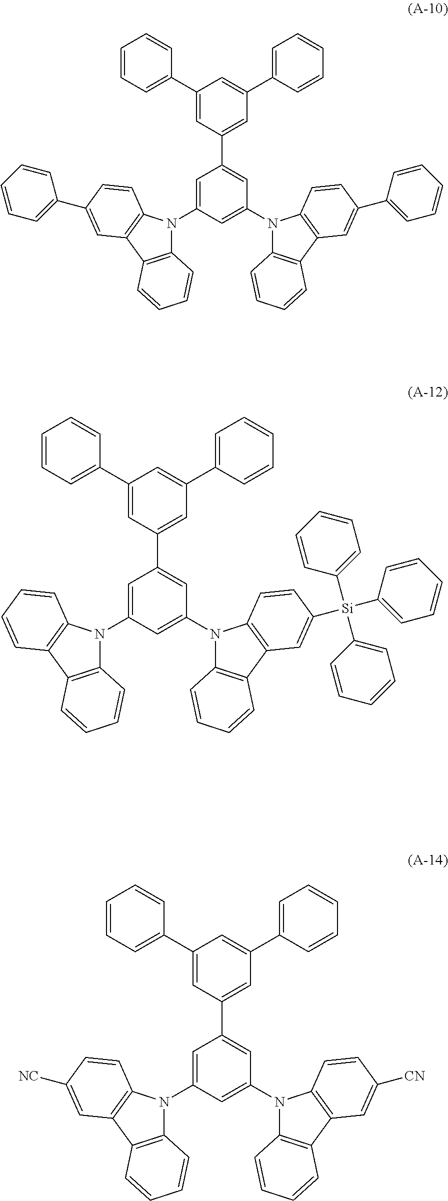

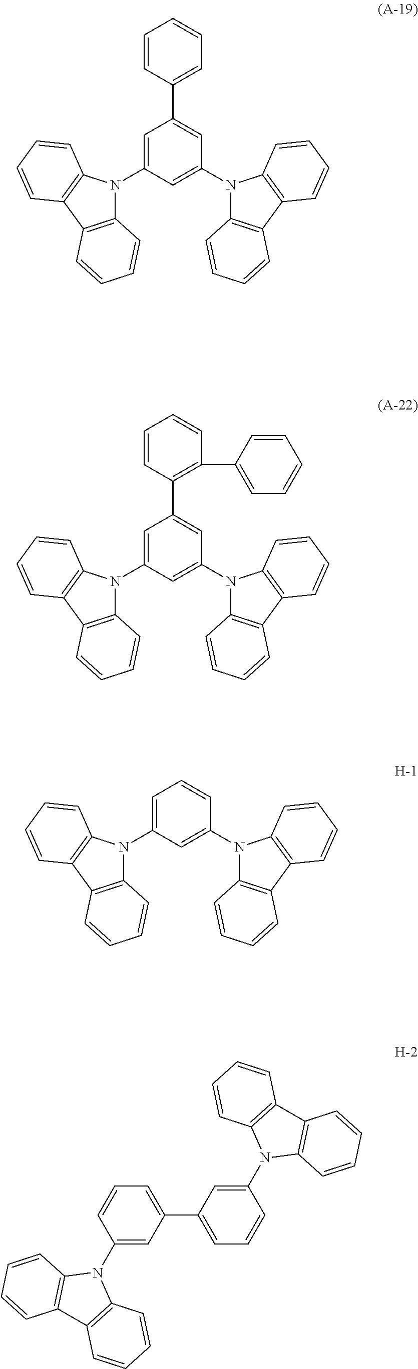

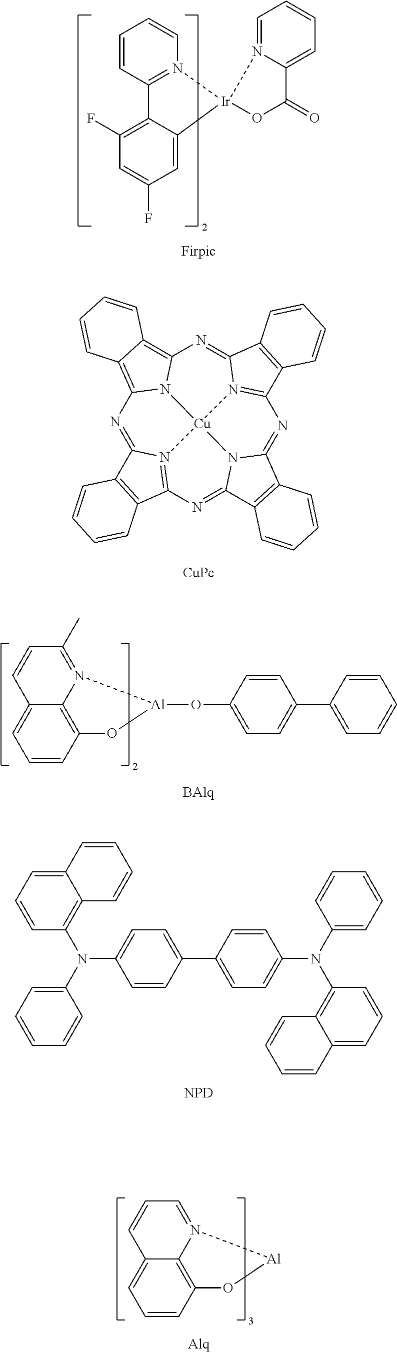

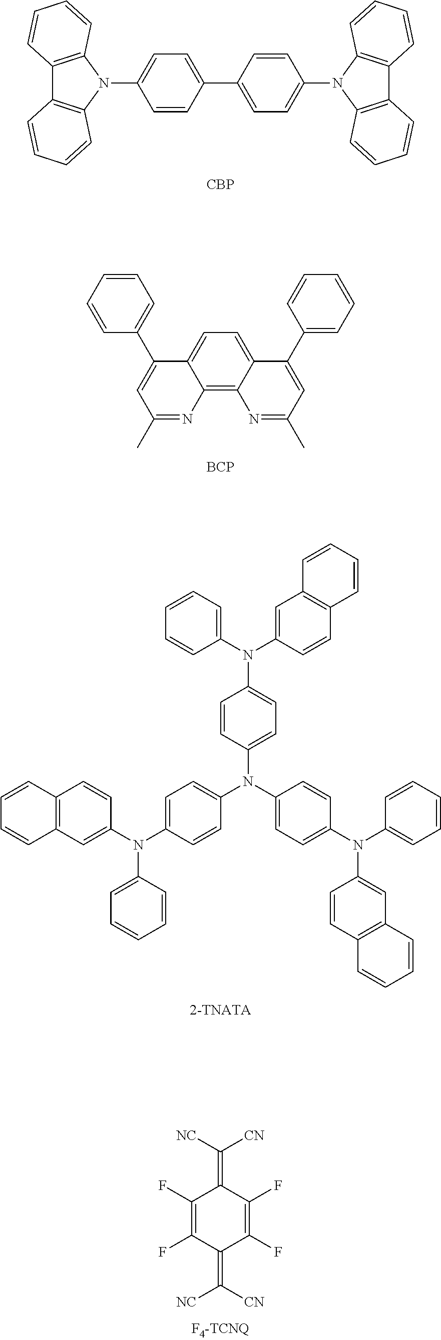

### INDUSTRIAL APPLICABILITY

The organic electroluminescence device of the present invention exhibits superior device properties during driving at high temperatures. Specifically, the organic electroluminescence device of the present invention exhibits superior external quantum efficiency and high durability during driving at high temperatures, and small variation in chromaticity and small increase in voltage after high-temperature driving.

Although the present invention has been described in detail with reference to specific embodiments, it will be apparent to those skilled in the art that various variations and modifications are possible within the spirit and scope of the present invention.

This application claims the benefit of Japanese Patent Application No. 2010-007536, filed on Jan. 15, 2010, Japanese Patent Application No. 2010-116665, filed on May 20, 2010, and Japanese Patent Application No. 2010-263017, filed on Nov. 25, 2010 which are herein incorporated by reference as if fully set forth herein.

### EXPLANATION OF REFERENCE NUMERALS AND SYMBOLS

2 . . . Substrate
3 . . . Anode
4 . . . Hole injection layer
5 . . . Hole transporting layer
6 . . . Light emitting layer
7 . . . Hole block layer
8 . . . Electron transporting layer
9 . . . Cathode
10 . . . Organic electroluminescence device(organic EL device)
11 . . . Organic layer
12 . . . Protective layer
14 . . . Adhesive layer
16 . . . Sealing container
20 . . . Light emission apparatus
30 . . . Light scattering member
30A . . . Light incident surface
30B . . . Light emission surface
31 . . . Transparent substrate
32 . . . Particle
40 . . . Illumination apparatus

1. An organic electroluminescence device, comprising on a substrate:
a pair of electrodes; and
at least one layer of an organic layer including a light emitting layer disposed between the electrodes,
wherein the light emitting layer contains at least one compound represented by Formula (PI-1), and
any layer of the at least one layer of an organic layer contains at least one compound represented by Formula (1): 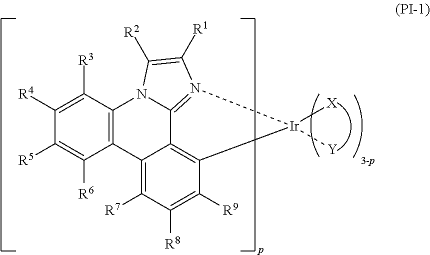
wherein in Formula (PI-1), each of R¹ to R⁹ independently represents a hydrogen atom or a substitutent, and the substituents represented by R¹ to R⁹ may be combined together to form a ring;
(X-Y) represents a monoanionic bidentate ligand; and
p represents an integer of 1 to 3: 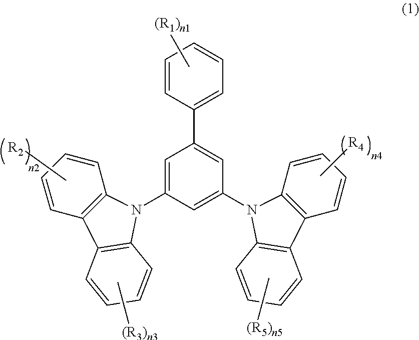
wherein in Formula (1), R₁ represents an alkyl group, an aryl group or a silyl group and may further have a substituent Z, provided that R₁ does not represent a carbazolyl group or a perfluoroalkyl alkyl group, and when R₁ is present in plural, each of a plurality of R₁'s may be the same as or different from every other R₁, and a plurality of R₁'s may be combined together to form an aryl ring which may have a substituent Z;
each of R₂ to R₅ independently represents an alkyl group, an aryl group, a silyl group, a cyano group or a fluorine atom and may further have a substituent Z, and when each of R₂ to R₅ is present in plural, each of a plurality of R₂'s to a plurality of R₅'s may be the same as or different from every other R₂ to R₅, respectively;
the substituent Z represents an alkyl group, an alkenyl group, an aryl group, an aromatic heterocyclic group, an alkoxy group, a phenoxy group, a fluorine atom, a silyl group, an amino group, a cyano group or a group formed by a combination thereof, and a plurality of the substituent Z's may be combined together to form an aryl group;
n1 represents an integer of 0 to 5; and
each of n2 to n5 independently represents an integer of 0 to 4.

2. The organic electroluminescence device according to claim 1,
wherein in Formula (PI-1), p is 3.

3. The organic electroluminescence device according to claim 1,
wherein the compound represented by Formula (1) is used in the light emitting layer.

4. The organic electroluminescence device according to claim 1,
wherein the compound represented by Formula (1) is used in a layer disposed between the light emitting layer and a cathode.

5. The organic electroluminescence device according to claim 1,
wherein the compound represented by Formula (1) is used in a layer disposed between the light emitting layer and an anode.

6. The organic electroluminescence device according to claim 1,
wherein the compound represented by Formula (1) above is represented by the following Formula (2): 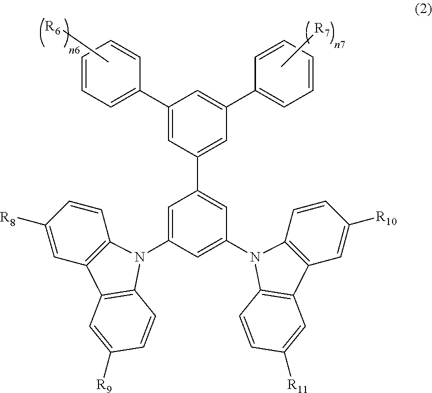
wherein in Formula (2), each of R₆ and R₇ independently represents an alkyl group which may have a substituent Z, an aryl group which may have an alkyl group, a cyano group or a fluorine atom, and when each of R₆ and R₇ is present in plural, each of a plurality of R₆'s and a plurality of R₇'s may be the same as or different from every other R₆ and R₇, respectively, and each of the plurality of R₆'s and the plurality of R₇'s may be combined together to form an aryl ring that may have a substituent Z;
each of n6 and n7 independently represents an integer of 0 to 5;
each of R₈ to R₁₁ independently represents a hydrogen atom, an alkyl group which may have a substituent Z, an aryl group which may have an alkyl group, a silyl group which may have a substituent Z, a cyano group or a fluorine atom; and
the substituent Z represents an alkyl group, an alkenyl group, an aryl group, an aromatic heterocyclic group, an alkoxy group, a phenoxy group, a fluorine atom, a silyl group, an amino group, a cyano group or a group formed by a combination thereof, and a plurality of substituent Z's may be combined together to form an aryl group.

7. The organic electroluminescence device according to claim 6,
wherein in Formula (PI-1), each of R¹ to R⁹ independently represents a hydrogen atom, an alkyl group, an aryl group, a cyano group or a fluorine atom, R¹ to R⁹ may be combined together to form an aryl group, and p is 3, in Formula (2), each of R₆ and R₇ independently represents an alkyl group or an aryl group which may have an alkyl group, each of n₆ and n₇ independently represents an integer of 0 to 2, each of R₈ to R₁₁ independently represents a hydrogen atom, an alkyl group, an aryl group which may have an alkyl group, a silyl group substituted by an alkyl group or a phenyl group, a cyano group or a fluorine atom.

8. The organic electroluminescence device according to claim 1,
wherein in Formula (PI-1), R⁸ is a hydrogen atom or a fluorine atom.

9. The organic electroluminescence device according to claim 1, further comprising:
an electron injection layer disposed between the electrodes,
wherein the electron injection layer contains an electron donating dopant.

10. The organic electroluminescence device according to claim 1, further comprising:
a hole injection layer disposed between the electrodes,
wherein the hole injection layer contains a hole accepting dopant.

11. The organic electroluminescence device according to claim 1,
wherein at least one layer of the organic layer disposed between the pair of electrodes is formed by a solution coating process.

12. A light emitting layer, comprising:
a compound represented by Formula (PI-1) and compound represented by Formula (1): 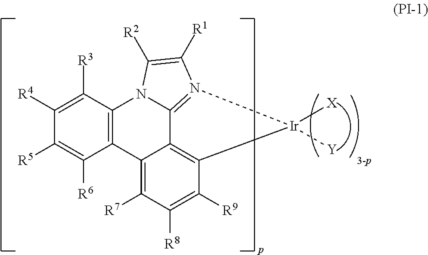
wherein in Formula (PI-1), each of R¹ to R⁹ independently represents a hydrogen atom or a substitutent, and the substituents represented by R¹ to R⁹ may be combined together to form a ring;
(X-Y) represents a monoanionic bidentate ligand; and
p represents an integer of 1 to 3: 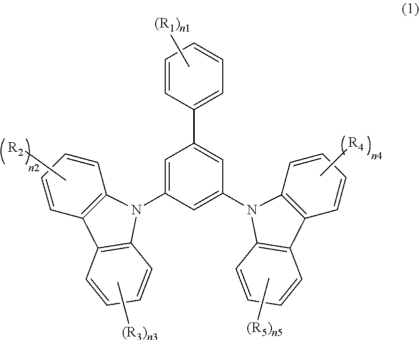
wherein in Formula (1), R₁ represents an alkyl group, an aryl group or a silyl group and may further have a substituent Z, provided that R₁ does not represent a carbazolyl group or a perfluoroalkyl alkyl group, and when R₁ is present in plural, each of a plurality of R₁'s may be the same as or different from every other R₁, and a plurality of R₁'s may be combined together to form an aryl ring which may have a substituent Z;
each of R₂ to R₅ independently represents an alkyl group, an aryl group, a silyl group, a cyano group or a fluorine atom and may further have a substituent Z, and when each of R₂ to R₅ is present in plural, each of a plurality of R₂'s to a plurality of R₅'s may be the same as or different from every other R₂ to R₅, respectively;
the substituent Z represents an alkyl group, an alkenyl group, an aryl group, an aromatic heterocyclic group, an alkoxy group, a phenoxy group, a fluorine atom, a silyl group, an amino group, a cyano group or a group formed by a combination thereof, and a plurality of the substituent Z's may be combined together to form an aryl group;
n1 represents an integer of 0 to 5; and
each of n2 to n5 independently represents an integer of 0 to 4.

13. A composition, comprising:
a compound represented by Formula (PI-1) and a compound represented by Formula (1): 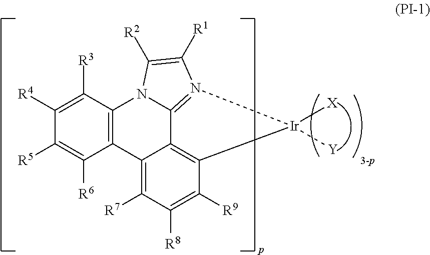
wherein in Formula (PI-1), each of R¹ to R⁹ independently represents a hydrogen atom or a substitutent, and the substituents represented by R¹ to R⁹ may be combined together to form a ring;
(X-Y) represents a monoanionic bidentate ligand; and
p represents an integer of 1 to 3: 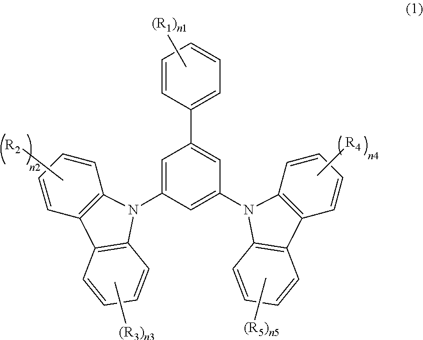
wherein in Formula (1), R₁ represents an alkyl group, an aryl group or a silyl group and may further have a substituent Z, provided that R₁ does not represent a carbazolyl group or a perfluoroalkyl alkyl group, and when R₁ is present in plural, each of a plurality of R₁'s may be the same as or different from every other R₁, and a plurality of R₁'s may be combined together to form an aryl ring which may have a substituent Z;
each of R₂ to R₅ independently represents an alkyl group, an aryl group, a silyl group, a cyano group or a fluorine atom and may further have a substituent Z, and when each of R₂ to R₅ is present in plural, each of a plurality of R₂'s to a plurality of R₅'s may be the same as or different from every other R₂ to R₅, respectively;
the substituent Z represents an alkyl group, an alkenyl group, an aryl group, an aromatic heterocyclic group, an alkoxy group, a phenoxy group, a fluorine atom, a silyl group, an amino group, a cyano group or a group formed by a combination thereof, and a plurality of the substituent Z's may be combined together to form an aryl group;
n1 represents an integer of 0 to 5; and
each of n2 to n5 independently represents an integer of 0 to 4.

14. A light emission apparatus using the organic electroluminescence device according to claim 1.

15. A display apparatus using the organic electroluminescence device according to claim 1.

16. An illumination apparatus using the organic electroluminescence device according to claim 1.
